(19) United States
(12) Patent Application Publication
(10) Pub. No.: US 2024/0188317 A1
(43) Pub. Date: Jun. 6, 2024

(54) LIGHT EMITTING ELEMENT, DISPLAY DEVICE, MANUFACTURING METHOD OF LIGHT EMITTING ELEMENT, AND MANUFACTURING METHOD OF DISPLAY DEVICE

(71) Applicant: SHARP KABUSHIKI KAISHA, Sakai City, Osaka (JP)

(72) Inventors: YOSHIHIRO UETA, Sakai City, Osaka (JP); YASUSHI ASAOKA, Sakai City, Osaka (JP); Yuma YAGUCHI, Sakai City, Osaka (JP)

(21) Appl. No.: 18/279,020

(22) PCT Filed: Mar. 30, 2021
(86) PCT No.: PCT/JP2021/013457

§ 371 Date: Aug. 25, 2023

(51) Int. Cl. H10K 50/115; H10K 59/12; H10K 59/122; H10K 71/12

(52) U.S. Cl. CPC H10K 50/115; H10K 59/1201; H10K 59/122; H10K 71/12

(57) ABSTRACT

A light-emitting element includes an anode, a light-emitting layer, and a cathode disposed in this order. The light-emitting layer includes a plurality of quantum dots and an insulating material. An average value of a gap between a quantum dot in an end face portion of the light-emitting layer on the anode side and an end face of the light-emitting layer on the anode side is less than an average value of a gap between a quantum dot in an end face portion of the light-emitting layer on the cathode side and an end face of the light-emitting layer on the cathode side. Further, a display device includes a bank separating the light-emitting elements on a subpixel-by-subpixel basis. The light-emitting layer includes a main light-emitting portion including a light-emitting material, and an outer edge portion disposed at a position surrounding the main light-emitting portion in plan view of a substrate and including a deactivation material in which the light-emitting material is deactivated. The bank includes a forwardly tapered face on a side surface, and is in contact with the outer edge portion at the forwardly tapered face.

### TECHNICAL FIELD

The disclosure relates to a light-emitting element and a display device including a plurality of the light-emitting elements.

### BACKGROUND ART

PTL 1 discloses a technique of forming, in a light-emitting element including a light-emitting layer containing quantum dots (semiconductor nanoparticles), a filling material between the quantum dots in order to reduce a leakage current.

### CITATION LIST

### Patent Literature

PTL 1: JP 2007-95685 A

### SUMMARY OF INVENTION

### Technical Problem

The present inventors discovered configurations of a light-emitting element and a display device that further improve characteristics of the light-emitting element.

### Solution to Problem

A light-emitting element according to an aspect of the disclosure includes an anode, a light-emitting layer, and a cathode. The anode, the light-emitting layer, and the cathode are disposed in this order. The light-emitting layer includes a plurality of quantum dots and an insulating material. An average value of a gap between a quantum dot of the plurality of quantum dots in an end face portion of the light-emitting layer on a side of the anode and an end face of the light-emitting layer on the side of the anode is less than an average value of a gap between a quantum dot of the plurality of quantum dots in an end face portion of the light-emitting layer on a side of the cathode and an end face of the light-emitting layer on the side of the cathode.

Further, a method for manufacturing a light-emitting element according to another aspect of the disclosure is a method for manufacturing a light-emitting element including an anode, a light-emitting layer, and a cathode disposed in this order. The method includes forming the anode, forming the light-emitting layer including a plurality of quantum dots and an insulating material, and forming the cathode. The forming the light-emitting layer includes forming a quantum dot material layer including the plurality of quantum dots, and forming an insulating material layer including the insulating material. An average value of a gap between a quantum dot of the plurality of quantum dots in an end face portion of the light-emitting layer on a side of the anode and an end face of the light-emitting layer on the side of the anode is less than an average value of a gap between a quantum dot of the plurality of quantum dots in an end face portion of the light-emitting layer on a side of the cathode and an end face of the light-emitting layer on the side of the cathode.

Further, a display device according to another aspect of the disclosure includes a substrate, a plurality of light-emitting elements disposed on a subpixel-by-subpixel basis on the substrate, and a bank separating the plurality of light-emitting elements on a subpixel-by-subpixel basis. Each of the plurality of light-emitting elements includes an anode, a light-emitting layer, and a cathode disposed in this order. The light-emitting layer includes a main light-emitting portion including a light-emitting material, and an outer edge portion disposed at a position surrounding the main light-emitting portion in plan view of the substrate, and including a deactivation material in which the light-emitting material is deactivated. The bank includes a forwardly tapered face on a side surface, and is in contact with the outer edge portion at the forwardly tapered face.

Further, a method for manufacturing a display device according to another aspect of the disclosure is a method for manufacturing a display device including a plurality of light-emitting elements formed on a substrate on a subpixel-by-subpixel basis, the plurality of light-emitting elements each including an anode, a light-emitting layer, and a cathode disposed in this order. The method includes, in this order, forming, on the substrate, a bank separating the plurality of light-emitting elements on a subpixel-by-subpixel basis and being in contact with the light-emitting layer, forming a light-emitting material layer including a light-emitting material of the light-emitting layer, forming a protection layer in an upper layer overlying the light-emitting material layer, and patterning the light-emitting material layer and the protection layer on a subpixel-by-subpixel basis by dry etching or wet etching the light-emitting material layer and the protection layer to form the light-emitting layer. A face of the bank in contact with the light-emitting layer is a forwardly tapered face.

### Advantageous Effects of Invention

Characteristics of a light-emitting element are improved and a display quality or a lifetime of a display device including the light-emitting element is improved.

### BRIEF DESCRIPTION OF DRAWINGS

FIG. 1 is a schematic view illustrating a side cross section of a display device according to a first embodiment, and an enlarged schematic view of the side cross section in the vicinity of a light-emitting layer.

FIG. 2 is a schematic view of the display device according to the first embodiment, in plan view.

FIG. 3 is an enlarged schematic view of the vicinity of a certain pixel of the display device according to the first embodiment, in plan view.

FIG. 4 is an enlarged schematic view of the side cross section of the display device according to the first embodiment, in the vicinity of a bank and the light-emitting layer.

FIG. 5 is a schematic view for illustrating, by comparison with a light-emitting element according to a comparative embodiment, a mechanism for reducing a reactive current realized by the light-emitting element according to the first embodiment.

FIG. 6 is a graph showing a relationship between a reactive current and an external quantum efficiency of the light-emitting element according to the comparative embodiment.

FIG. 7 is a flowchart for describing a method for manufacturing the display device according to the first embodiment.

FIG. 8 is a flowchart for describing a method for forming the light-emitting layer of the light-emitting element according to the first embodiment.

FIG. 9 illustrates schematic process cross-sectional views for describing the method for forming the light-emitting layer of the light-emitting element according to the first embodiment.

FIG. 10 is an enlarged schematic view of a side cross section of the display device according to a second embodiment, in the vicinity of the light-emitting layer.

FIG. 11 is a flowchart for describing a method for forming the light-emitting layer of a light-emitting element according to the second embodiment.

FIG. 12 illustrates schematic process cross-sectional views for describing the method for forming the light-emitting layer of the light-emitting element according to the second embodiment.

FIG. 13 is an enlarged schematic view of a side cross section of the display device according to a third embodiment, in the vicinity of the light-emitting layer.

FIG. 14 shows graphs for evaluating characteristics of the light-emitting elements according to the first embodiment and a third embodiment in comparison with characteristics of the light-emitting element according to the comparative embodiment.

FIG. 15 is a flowchart for describing a method for forming the light-emitting layer of the light-emitting element according to the third embodiment.

FIG. 16 is an enlarged schematic view of a side cross section of the display device according to a fourth embodiment, in the vicinity of the light-emitting layer.

FIG. 17 is a flowchart for describing a method for forming the light-emitting layer of the light-emitting element according to the fourth embodiment.

FIG. 18 is an enlarged schematic view of the vicinity of a certain pixel of the display device according to a fifth embodiment, in plan view.

FIG. 19 is a schematic view of a side cross section of the display device according to the fifth embodiment.

FIG. 20 is an enlarged schematic view of the side cross section of the display device according to the fifth embodiment, in the vicinity of the bank and a light-emitting layer.

FIG. 21 is a flowchart for describing a method for forming the light-emitting layer of the light-emitting element according to the fifth embodiment.

FIG. 22 illustrates schematic process cross-sectional views for describing the method for forming the light-emitting layer of the light-emitting element according to the fifth embodiment.

### DESCRIPTION OF EMBODIMENTS

### First Embodiment

### Overview of Display Device

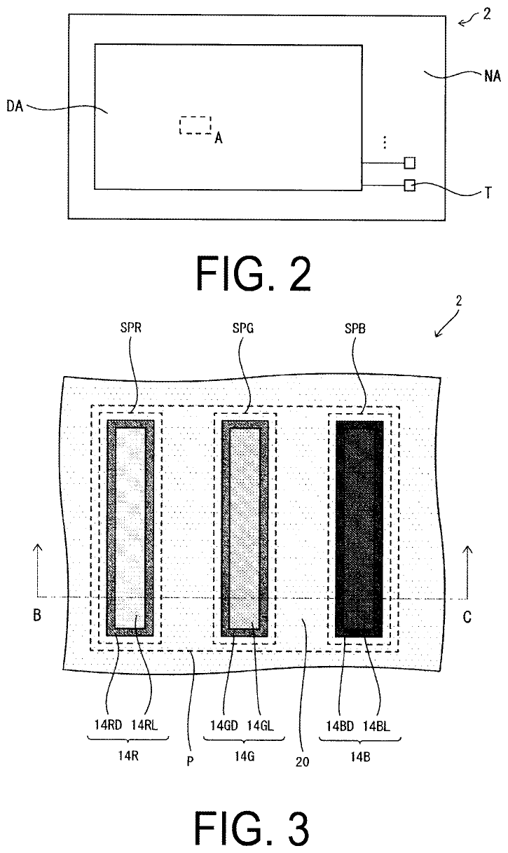

FIG. 2 is a schematic view of a display device 2 according to the present embodiment, in plan view of a substrate 4 described below. As illustrated in FIG. 2, the display device 2 according to the present embodiment includes a display region DA that performs display by the extraction of light emission from subpixels described below, and a frame region NA surrounding a periphery of the display region DA. In the frame region NA, a terminal T into which is input a signal for driving each light-emitting element of the display device 2 is formed.

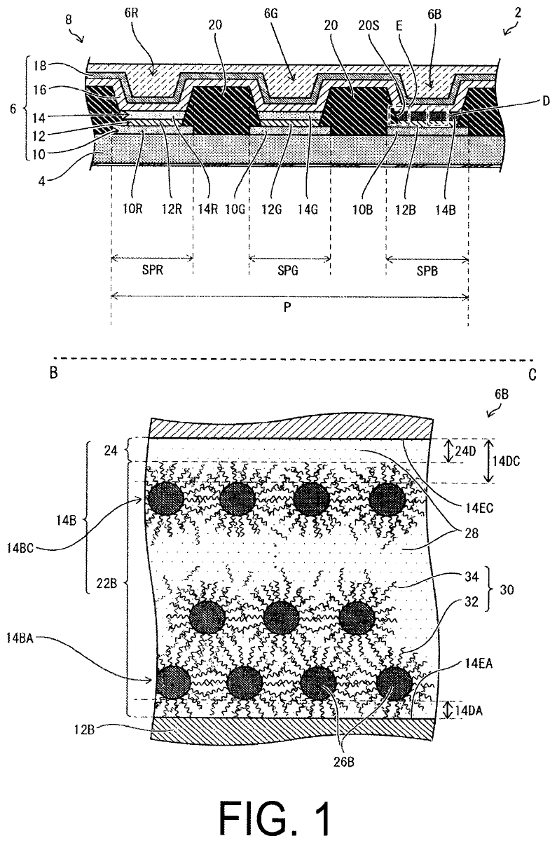

FIG. 3 is an enlarged view illustrating a region A that is a partial region of the display region DA in the schematic view illustrated in FIG. 2. FIG. 1 is a schematic cross-sectional view of the display device 2 according to the present embodiment, and an enlarged schematic view illustrating a partial region of the cross section. The schematic cross-sectional view of the display device 2 illustrated in FIG. 1 is a cross-sectional view taken along an arrow line B-C in FIG. 3. The enlarged schematic view of the display device 2 illustrated in FIG. 1 is an enlarged view of a region D illustrated in FIG. 1. Note that, in FIG. 3, a sealing layer 8, an electron transport layer 16, and a cathode 18, described in detail below, are not illustrated in order to more clearly illustrate pixels and subpixels, described in detail below.

At a position overlapping the display region DA in plan view, the display device 2 according to the present embodiment includes a plurality of pixels. Further, each pixel includes a plurality of subpixels. In the schematic cross-sectional view of the display device 2 illustrated in FIG. 1 and in FIG. 3, a pixel P among the plurality of pixels included in the display device 2 is illustrated. In particular, the pixel P includes a red subpixel SPR, a green subpixel SPG, and a blue subpixel SPB.

The display device 2 according to the present embodiment includes, for example, as illustrated in FIG. 1, the display device 2 according to the present embodiment includes the substrate 4, a light-emitting element layer 6 on the substrate 4, and the sealing layer 8 covering the light-emitting element layer 6.

For example, the substrate 4 has a structure obtained by forming thin film transistors (TFTs; not illustrated) on a flexible film substrate including a PET film or the like. Furthermore, the light-emitting element layer 6 and the sealing layer 8 having flexibility are formed on the substrate 4. In this case, the display device 2 according to the present embodiment realizes a flexible display device that can be bent with at least one of the substrate 4 or the sealing layer 8 as an inner side. However, the display device 2 according to the present embodiment is not limited thereto, and may include the substrate 4, the light-emitting element layer 6, or the sealing layer 8 having rigidity.

Note that, in the present specification, a direction from a light-emitting layer 14, described below, of the light-emitting element layer 6 to an anode 10 is referred to as a “downward direction”, and a direction from the light-emitting layer 14 to the cathode 18 is referred to as an “upward direction”.

### Light-Emitting Element

The light-emitting element layer 6 includes the anode 10, a hole transport layer 12, the light-emitting layer 14, the electron transport layer 16, and the cathode 18 in this order from the substrate 4 side. In other words, the light-emitting element layer 6 includes the light-emitting layer 14 between the two electrodes of the anode 10 and the cathode 18. The anode 10 of the light-emitting element layer 6 formed in an upper layer overlying the substrate 4 is formed in an island shape for each subpixel described above, and electrically connected with each of the TFTs of the substrate 4.

In the present embodiment, the light-emitting element layer 6 includes a plurality of light-emitting elements and, in particular, includes one light-emitting element for each subpixel. In the present embodiment, for example, the light-emitting element layer 6 includes, as the light-emitting elements, a red light-emitting element 6R in the red subpixel SPR, a green light-emitting element 6G in the green subpixel SPG, and a blue light-emitting element 6B in the blue subpixel SPB. Hereinafter, in the present specification, unless otherwise specified, “light-emitting element” refers to any one of the red light-emitting element 6R, the green light-emitting element 6G, and the blue light-emitting element 6B included in the light-emitting element layer 6.

Herein, the anode 10, the hole transport layer 12, and the light-emitting layer 14 are individually formed on a subpixel-by-subpixel basis. In particular, in the present embodiment, the anode 10 includes an anode 10R for the red light-emitting element 6R, an anode 10G for the green light-emitting element 6G, and an anode 10B for the blue light-emitting element 6B. Further, the hole transport layer 12 includes a hole transport layer 12R for the red light-emitting element 6R, a hole transport layer 12G for the green light-emitting element 6G, and a hole transport layer 12B for the blue light-emitting element 6B. Furthermore, the light-emitting layer 14 includes a red light-emitting layer 14R that emits red light, a green light-emitting layer 14G that emits green light, and a blue light-emitting layer 14B that emits blue light. On the other hand, the electron transport layer 16 and the cathode 18 are formed in common to the plurality of subpixels.

Accordingly, in the present embodiment, the red light-emitting element 6R is composed of the anode 10R, the hole transport layer 12R, the red light-emitting layer 14R, the electron transport layer 16, and the cathode 18. Further, the green light-emitting element 6G is composed of the anode 10G, the hole transport layer 12G, the green light-emitting layer 14G, the electron transport layer 16, and the cathode 18. Furthermore, the blue light-emitting element 6B is composed of the anode 10B, the hole transport layer 12G, the blue light-emitting layer 14B, the electron transport layer 16, and the cathode 18.

Here, the blue light refers to, for example, light having an emission center wavelength in a wavelength band of equal to or greater than 400 nm and equal to or less than 500 nm. The green light refers to, for example, light having an emission center wavelength in a wavelength band of greater than 500 nm and equal to or less than 600 nm. The red light refers to, for example, light having an emission center wavelength in a wavelength band of greater than 600 nm and equal to or less than 780 nm.

Note that the light-emitting element layer 6 according to the present embodiment is not limited to the configuration described above, and may further include an additional layer between the anode 10 and the cathode 18. For example, the light-emitting element layer 6 may further include a hole injection layer between the anode 10 and the hole transport layer 12. Further, note that the light-emitting element layer 6 may further include an electron injection layer between the electron transport layer 16 and the cathode 18.

The anode 10 and the cathode 18 include conductive materials and are electrically connected to the light-emitting layer 14. The anode 10 is a pixel electrode formed into an island shape on a subpixel-by-subpixel basis, and the cathode 18 is a common electrode formed in common to the plurality of subpixels. For example, of the anode 10 and the cathode 18, the electrode closer to a display surface of the display device 2 is a semitransparent electrode, and the other is a reflective electrode.

The hole transport layer 12 includes a material having hole transport properties, and has a function of transporting holes injected from the anode 10 into the light-emitting layer 14. The hole transport layer 12 may have a function of inhibiting transport of electrons from the light-emitting layer 14 to the anode 10. The electron transport layer 16 includes a material having electron transport properties, and has a function of transporting electrons injected from the cathode 18 into the light-emitting layer 14. The electron transport layer 16 may have a function of inhibiting transport of holes from the light-emitting layer 14 to the cathode 18. The hole transport layer 12 and the electron transport layer 16 transmit at least a portion of the light from each of the light-emitting layers 14.

The light-emitting layer 14 is a layer that emits light as a result of an occurrence of recombination between the holes transported, via the hole transport layer 12, from the anode 10 and the electrons transported, via the electron transport layer 16, from the cathode 18. The light-emitting layer 14 includes a quantum dot material described below as a light-emitting material. As a result, each light-emitting element according to the present embodiment is a quantum dot light-emitting diode (QLED).

Note that the display device 2 according to the present embodiment includes the light-emitting element including the anode 10 on the substrate 4 side, but is not limited thereto. For example, the light-emitting element layer 6 included in the display device 2 according to the present embodiment may include the cathode 18, the electron transport layer 16, the light-emitting layer 14, the hole transport layer 12, and the anode 10 layered in this order from the substrate 4 side. In this case, the cathode 18 is a pixel electrode formed into an island shape on a subpixel-by-subpixel basis, and the anode 10 is a common electrode formed in common to the plurality of subpixels. Further, the electron transport layer 16 may be formed on a subpixel-by-subpixel basis, and the hole transport layer 12 may be formed in common to the plurality of subpixels.

### Bank and Sealing Layer

The display device 2 according to the present embodiment further includes a bank 20 on an upper face of the substrate 4. The bank 20 includes, for example, a coatable resin material including polyimide, and is formed at positions extending across boundaries between subpixels adjacent to each other in plan view. Therefore, the light-emitting element layer 6 is separated into the red light-emitting element 6R, the green light-emitting element 6G, and the blue light-emitting element 6B by the banks 20. Note that, as illustrated in FIG. 1, the bank 20 may be formed at a position covering each peripheral end portion of the anode 10.

For example, the bank 20 includes a coatable photosensitive resin. In particular, in the present embodiment, the bank 20 includes a positive-working photosensitive resin. The banks 20 each include a side surface 20S. Herein, the bank 20 is formed with an area thereof in plan view gradually decreasing in general from the substrate 4 side toward the sealing layer 8 side. Therefore, among the normal directions of the side surfaces 20S, the direction toward an interior side of the bank 20 is more so a direction from the sealing layer 8 toward the substrate 4 than a planar direction of the upper face of the substrate 4 that is the face on which the bank 20 is formed.

When a specific member includes a side surface and the specific member is formed on a specific face, an angle formed by an outer surface side of the side surface and the specific face is an obtuse angle. In this case, the side surface is referred to as a forwardly tapered face in the present specification. For example, in a truncated regular quadrangular pyramid in which an area of a lower base is large compared with an area of an upper base, all side surfaces of the truncated regular quadrangular pyramid are forwardly tapered faces.

In the present embodiment, the bank 20 is formed on the upper face of the substrate 4. Further, an angle formed by an outer surface side of the side surface 20S of the bank 20 and the upper face of the substrate 4 is an obtuse angle. Accordingly, the side surface 20S of the bank 20 is a forwardly tapered face. Therefore, in the present embodiment, with the light-emitting layer of each light-emitting element separated by the bank 20 having the forwardly tapered face on the side surface, the light-emitting layer is in contact with the side surface 20S that is the forwardly tapered face.

The sealing layer 8 covers the light-emitting element layer 6 and the banks 20 and seals each light-emitting element included in the display device 2. The sealing layer 8 reduces permeation of foreign matters including moisture and the like into the light-emitting element layer 6 and the like from outside the display device 2 on the sealing layer 8 side. The sealing layer may have, for example, a layered structure of an inorganic sealing film made of an inorganic material and an organic sealing film made of an organic material. The inorganic sealing film is formed by chemical vapor deposition (CVD) and constituted by a silicon oxide film, a silicon nitride film, a silicon oxynitride film, or a layered film of these, for example. The organic sealing film is constituted by, for example, a coatable resin material including polyimide.

### Quantum Dot and Insulating Material

The light-emitting layer 14 according to the present embodiment will now be described in more detail with reference to an enlarged schematic view in the vicinity of the light-emitting layer 14 illustrated in FIG. 1. In particular, the enlarged schematic view is an enlarged schematic view illustrating the vicinity of the blue light-emitting layer 14B of the blue light-emitting element 6B of the display device 2 according to the present embodiment. Herein, unless otherwise specified, the red light-emitting layer 14R and the green light-emitting layer 14G according to the present embodiment have the same configuration as that of the blue light-emitting layer 14B except for blue quantum dots described below. Note that the enlarged schematic view of FIG. 1 is an enlarged view illustrating a portion of a main light-emitting portion 14BL, described below, of the blue light-emitting layer 14B, in an enlarged manner.

Note that, in the present specification, the term “quantum dot” refers to a particle with an outermost shell having a maximum width of 100 nm or less. A shape of the quantum dot need only be within a range satisfying the maximum width described above, is not particularly limited, and is not limited to a spherical three-dimensional shape, in other words, a circular cross-sectional shape. The quantum dot may have, for example, a polygonal cross-sectional shape, a rod-like three-dimensional shape, a branch-like three-dimensional shape, a three-dimensional shape with unevenness on the outermost surface, or a shape obtained by combining these shapes.

As illustrated in the enlarged schematic view of the vicinity of the blue light-emitting layer 14B in FIG. 1, the blue light-emitting layer 14B includes a blue quantum dot layer 22B and an insulating layer 24 disposed in this order from the hole transport layer 12B side, in other words, the anode 10 side. The blue quantum dot layer 22B includes a plurality of blue quantum dots 26B, an insulating material 28, and a plurality of ligands 30. The insulating layer 24 includes the insulating material 28. In particular, the insulating layer 24 includes only the insulating material 28 among the materials included in the blue quantum dot layer 22B. Note that the insulating layer 24 need not be a layer having a completely uniform film thickness, and may include a portion having a different thickness compared with that of other portions, such as a portion having unevenness on any surface, for example.

The blue quantum dot 26B is a semiconductor nanoparticle that emits blue light by the recombination of holes and electrons injected into the blue light-emitting layer 14B. The blue quantum dot 261B may have, for example, a core-shell structure including a core including a material contributing to light emission and a shell surrounding the core. A material of the blue quantum dot 26B is not particularly limited as long as the material is a semiconductor nanoparticle that emits blue light, and may include a conventionally known material used for a quantum dot.

The blue quantum dot layer 22B includes the ligands 30 as a first compound that can be coordinated to the blue quantum dot 26B. The ligand 30 is, for example, a compound including at least, at one end of a carbon chain, a coordination functional group that can form a coordination bond with the blue quantum dot 26B. In the present embodiment, the ligands 30 include a binding ligand 32 that forms a coordination bond with the blue quantum dot 26B as a binding compound, and further include an excess ligand 34 that does not form a coordination bond with the blue quantum dot 26B and is dispersed in the insulating material 28 as an excess compound. The binding ligand 32 and the excess ligand 34 may have the same configuration except for the presence or absence of the coordination bond with the blue quantum dot 26B. The ligand 30 has a function of reducing aggregation of the blue quantum dots 26B, protecting outer surfaces of the blue quantum dots 26B, or the like. The ligand 30 may include, for example, the same material as a conventionally known material of a ligand that can be coordinated to a quantum dot.

In general, a ligand bonded to a quantum dot by a coordination bond is bound to the quantum dot by the coordination bond and therefore has a small diffusion coefficient compared with that of a ligand not bonded to a quantum dot and having the same molecular weight. This corresponds to the fact that the free energy of the ligand bonded to the quantum dot is low compared with that of a ligand not bonded to a quantum dot and having the same molecular weight. Accordingly, in the present embodiment, it can be said that the excess ligand 34 is a ligand having a higher free energy relative to molecular weight than the binding ligand 32.

The insulating material 28 is made of a material having a high electrical resistivity and a low carrier mobility compared to those of the material of the blue quantum dot 26B and the material of the ligand 30. The insulating material 28 included in the blue quantum dot layer 222B is filled between the blue quantum dots 26B. Further, in the present embodiment, the insulating material 28 included in the insulating layer 24 and the insulating material 28 included in the blue quantum dot layer 22B may be the same material and may be continuous or separate.

### End Face of Light-Emitting Layer and Structure in Vicinity of End Face

The insulating material 28 constitutes an end face 14EA on the anode 10 side and an end face 14EC on the cathode 18 side of the blue light-emitting layer 14B. Therefore, in the present embodiment, the hole transport layer 12B is in contact with the end face 14EA, and the electron transport layer 16 is in contact with the end face 14EC.

Herein, the blue quantum dot layer 22B includes an end face portion 14BA on the anode 10 side in the vicinity of the end face 14EA, and includes an end face portion 14BC on the cathode 18 side in the vicinity of the end face 14EC. The plurality of blue quantum dots 26B and the plurality of ligands 30 are positioned in the end face portion 14BA and the end face portion 14BC.

Note that, in the present embodiment, the end face portion 14BA refers to, for example, an area of the blue light-emitting layer 14B from the end face 14EA to a portion where 20 blue quantum dots 26B closest to the end face 14EA are positioned. Further, the end face portion 14BC refers to, for example, an area of the blue light-emitting layer 14B from the end face 14EC to a portion where 20 blue quantum dots 26B closest to the end face 14EC are positioned.

At least one of the binding ligand 32 coordinated to the blue quantum dot 26B positioned in the end face portion 14BA or the excess ligand 34 positioned around that blue quantum dot 26B is in contact with an end face of the blue quantum dot layer 22B on the anode 10 side. Accordingly, at least one of the ligands 30 positioned in the end face portion 14BA is in contact with the end face 14EA.

At least one of the binding ligand 32 coordinated to the blue quantum dot 26B positioned in the end face portion 14BC or the excess ligand 34 positioned around that blue quantum dot 26B is in contact with an end face of the blue quantum dot layer 22B on the cathode 18 side. Accordingly, at least one of the ligands 30 positioned in the end face portion 14BC is in contact with the end face 14EC with the insulating layer 24 interposed therebetween.

Note that FIG. 1 illustrates a portion of the ligands 30 positioned in the end face portion 14BA in contact with the end face of the blue quantum dot layer 22B on the anode 10 side, and a portion of the ligands 30 positioned in the end face portion 14BC in contact with the end face of the blue quantum dot layer 22B on the cathode 18 side. However, no such limitation is intended, and at least one of the blue quantum dots 26B positioned in the end face portion 14BA may be in contact with the end face of the blue quantum dot layer 22B on the anode 10 side. Further, at least one of the blue quantum dots 26B positioned in the end face portion 14BC may be in contact with the end face of the blue quantum dot layer 22B on the cathode 18 side.

Here, an average value of a gap between the blue quantum dot 26B in the end face portion 14BA and the end face 14EA is referred to as a gap 14DA, and an average value of a gap between the blue quantum dot 26B in the end face portion 14BC and the end face 14EC is referred to as a gap 14DC. For example, assume for the moment a cross section obtained by cutting the blue light-emitting layer 14B at an arbitrary cross section in the normal direction of any surface of the blue light-emitting layer 14B. In this case, in the present embodiment, the gap 14DA is an average value of the gaps between the end face 14EA and, among the blue quantum dots 26B facing the end face 14EA, 20 blue quantum dots 26B adjacent to each other, on the cut face. Further, the gap 14DC is an average value of the gaps between the end face 14EC and, among the blue quantum dots 26B facing the end face 14EC, 20 blue quantum dots 26B adjacent to each other, on the cut face. Note that, in the present specification, the gap between the blue quantum dot 26B and one end face of the end face 14EA and the end face 14EC is the shortest distance between an outer periphery of the blue quantum dot 26B and the end face, on the cut face described above.

In the present embodiment, the end face of the blue quantum dot layer 22B on the anode 10 side is identical to the end face 14EA and is in contact with the hole transport layer 12B. On the other hand, the end face of the blue quantum dot layer 22B on the cathode 18 side is separated from the end face 14EA due to the insulating layer 24. Therefore, the gap 14DA is smaller than the gap 14DC.

The red light-emitting layer 14R and the green light-emitting layer 14G according to the present embodiment have the same configuration as that of the blue light-emitting layer 14B except for including red quantum dots emitting red light and green quantum dots emitting green light instead of the blue quantum dots 26B, respectively. For example, with a quantum dot having a core-shell structure, a wavelength of light emitted can be controlled by controlling a particle size of the core. Accordingly, the red quantum dot and the green quantum dot may have, for example, the same configuration as that of the blue quantum dot 26B except for the particle size of the core.

### Main Light-Emitting Portion and Outer Edge Portion

As illustrated in FIG. 3, the red light-emitting layer 14R according to the present embodiment includes a main light-emitting portion 14RL and an outer edge portion 14RD.

Further, the green light-emitting layer 14G according to the present embodiment includes a main light-emitting portion 14GL and an outer edge portion 14GD. Further, the blue light-emitting layer 14B according to the present embodiment includes the main light-emitting portion 14BL and an outer edge portion 14BD. The outer edge portion 14RD, the outer edge portion 14G), and the outer edge portion 14BD, in plan view of the substrate 4, are disposed at positions surrounding the main light-emitting portion 14RL, the main light-emitting portion 14GL, and the main light-emitting portion 14BL, respectively.

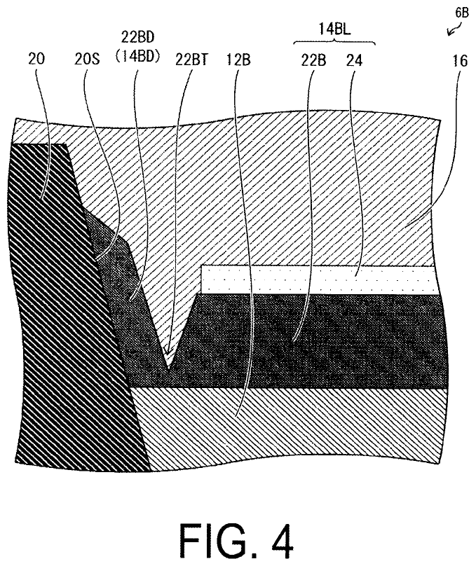

The main light-emitting portion and the outer edge portion of the light-emitting layer 14 according to the present embodiment will now be described in more detail with reference to an enlarged schematic view of the vicinity of an interface between the bank 20 and the light-emitting layer 14 illustrated in FIG. 4. In particular, the enlarged schematic view is an enlarged schematic view illustrating the vicinity of the interface between the bank 20 and the blue light-emitting layer 14B of the blue light-emitting element 6B of the display device 2 according to the present embodiment, and is an enlarged view illustrating a region E illustrated in FIG. 1. Herein, unless otherwise specified, the main light-emitting portion 14RL and the main light-emitting portion 14GL have the same configuration as that of the main light-emitting portion 14BL, and the outer edge portion 14RD and the outer edge portion 14GD have the same configuration as that of the outer edge portion 14), except for materials.

The main light-emitting portion 14BL includes the blue quantum dot layer 223 and the insulating layer 24 described above. Therefore, the main light-emitting portion 14BL includes the blue quantum dots 26B that are the light-emitting material included in the blue light-emitting layer 14B. On the other land, the outer edge portion 14BD includes a deactivation layer 22BD and does not include the insulating layer 24. The deactivation layer 22BD is in contact with the side surface 20S of the bank 20, and is continuous with the blue quantum dot layer 22B of the main light-emitting portion 14BL with a thin film portion 22BT, having a thinner thickness than a surrounding portion, interposed therebetween.

However, the deactivation layer 22BD need not be continuous with the main light-emitting portion 14BL, and may be formed as a separate body. In other words, the blue light-emitting layer 14B may not be formed between the main light-emitting portion 14BL and the outer edge portion 14BD, and the main light-emitting portion 14BL and the outer edge portion 14BD may be separated by the electron transport layer 16.

The deactivation layer 22BD includes a material in which the blue quantum dots 26B have been deactivated by oxidation, moisture permeation, physical damage, or the like.

Therefore, the deactivation layer 22BD has a low luminous efficiency compared with that of the blue quantum dot layer 22B. Otherwise, the deactivation layer 22BD may have the same configuration as that of the blue quantum dot layer 22B. Note that the outer edge portion 14RD and the outer edge portion 14GD according to the present embodiment have the same configuration as that of the outer edge portion 14BD except for inclusion of a deactivation layer including a material in which the red quantum dots were deactivated and a deactivation layer including a material in which the green quantum dots were deactivated, respectively. The effect of the deactivation layer 22BD will be described below in detail together with a method for forming the deactivation layer 22BD.

### Reactive Current

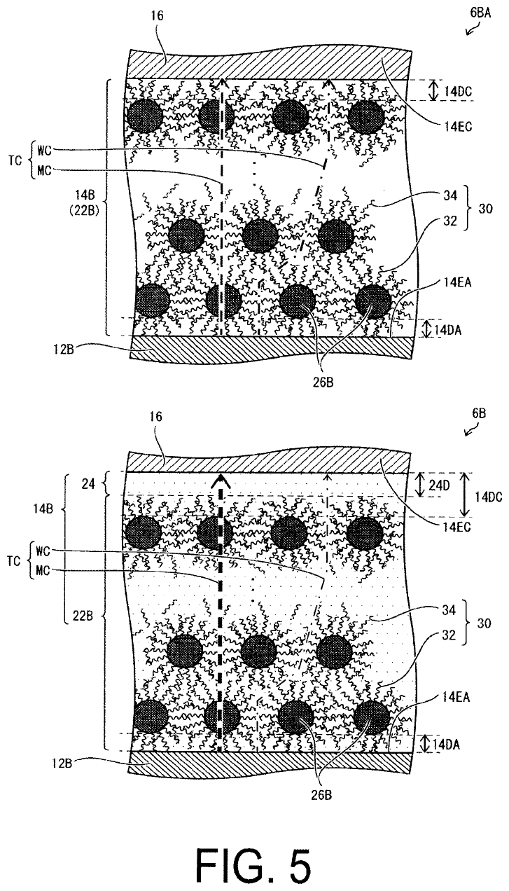

The effect of the blue light-emitting element 6B according to the present embodiment will be described by comparison with a blue light-emitting element 6BA according to a comparative embodiment. FIG. 5 is a diagram illustrating the blue light-emitting element 6B according to the present embodiment together with the blue light-emitting element 6BA according to the comparative embodiment, and is an enlarged schematic view illustrating a position corresponding to the enlarged schematic view of the vicinity of the blue light-emitting layer 14B of the blue light-emitting element 6B illustrated in FIG. 1.

In the blue light-emitting element 6BA according to the comparative embodiment, the blue light-emitting layer 14B does not include the insulating layer 24. Therefore, the end face 14EC of the blue quantum dot layer 22B on the cathode 18 side according to the comparative embodiment is in contact with the electron transport layer 16. Further, the blue quantum dot layer 22B according to the comparative embodiment does not include the insulating material 28. Otherwise, the blue light-emitting element 6BA according to the comparative embodiment has the same configuration as that of the blue light-emitting element 6B according to the present embodiment.

When the blue light-emitting element 6BA according to the comparative embodiment is driven and a potential difference is applied between the anode 10 and the cathode 18, a main current MC and a reactive current WC flow through the blue light-emitting layer 14B as illustrated in FIG. 5. The main current MC mainly flows through the blue quantum dots 26B, while the reactive current WC mainly flows through the binding ligands 32 or the excess ligands 34 around the blue quantum dots 26B.

In general, a reactive current that does not flow through a quantum dot does not contribute to a mechanism for transporting carriers to the quantum dot, and thus does not contribute to the light emission of the quantum dot. Further, a total current TC flowing through the entire blue light-emitting element 6BA is the sum of the main current MC and the reactive current WC. The total current TC does not significantly change as long as the potential difference between the electrodes of the blue light-emitting element 6BA is constant. Further, a power consumption of the blue light-emitting element 6BA depends on the total current TC.

Accordingly, when the reactive current WC is high compared with the main current MC, the current that does not contribute to the light emission of the blue quantum dot 26B increases, decreasing the luminous efficiency of the blue light-emitting element 6BA. Accordingly, an intensity of the light emission extracted from the blue light-emitting element 6BA relative to the power consumed by the blue light-emitting element 6BA is reduced.

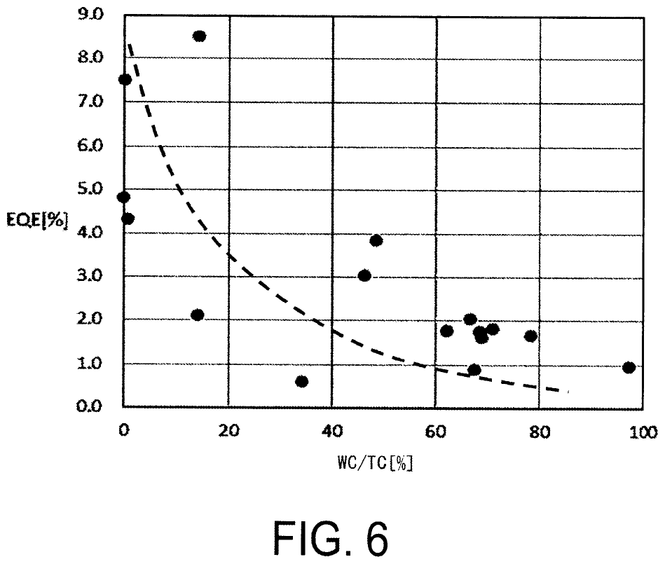

Further, when a ratio of the reactive current to the total current flowing through the light-emitting element is high, an external quantum efficiency of the light-emitting element decreases. FIG. 6 is a graph showing the relationship between the ratio of the reactive current to the total current and the external quantum efficiency of the light-emitting element according to the comparative embodiment. In the graph of FIG. 6, the horizontal axis represents the ratio (unit:percent) of the reactive current to the total current, and the vertical axis represents the external quantum efficiency (unit:percent) of the light-emitting element. FIG. 6 shows plotted data obtained by manufacturing a plurality of light-emitting elements having the same configuration as that of the blue light-emitting element 6BA, driving the light-emitting elements, and measuring the total current, the reactive current, and the external quantum efficiency of each.

The dotted line shown in FIG. 6 is an approximate curve derived from the data plotted in FIC. 6. As is clear from the approximate curve, when the ratio of the reactive current to the total current is high, the external quantum efficiency of the light-emitting element is low.

Some light-emitting elements have a low ratio of reactive current to total current and improved external quantum efficiency, but such light-emitting elements are manufactured by chance due to manufacturing errors in the manufacturing stage of the light-emitting elements. Therefore, in the comparative embodiment, it is difficult to reliably manufacture a light-emitting element having a high external quantum efficiency. Actually, as is clear from FIG. 6, the number of manufactured light-emitting elements having a low ratio of the reactive current to the total current and a high external quantum efficiency is extremely small compared with the number of manufactured light-emitting elements having a high ratio of the reactive current to the total current and a low external quantum efficiency.

Herein, in general, the reactive current WC flowing through the ligands 30 flows in the ligands 30 and between the ligands 30 mainly by hopping conduction. Therefore, the main component of the reactive current WC flowing through the light-emitting layer is proportional to the carrier mobility and the dielectric constant of the materials other than the quantum dots and to the applied voltage, and is inversely proportional to the film thickness of the light-emitting layer.

It is difficult to significantly change a dielectric constant of the light-emitting layer of the light-emitting element, even if the material is replaced. Further, the voltage applied to the light-emitting layer also depends on the intensity of light extracted from the light-emitting element, making it difficult to reduce the applied voltage. On the other hand, when a thickness of the light-emitting layer is excessively increased, a resistance of the entire light-emitting element increases. Accordingly, to reduce the reactive current flowing through the light-emitting layer, it is important to reduce the carrier mobility of the materials other than the quantum dots.

The blue light-emitting layer 14B included in the blue light-emitting element 6B according to the present embodiment includes the insulating material 28. The carrier mobility of the insulating material 28 is lower than the carrier mobility of the ligand 30. Therefore, in the blue light-emitting layer 14B according to the present embodiment, the reactive current WC flowing through the ligand 30 without going through the blue quantum dot 26B can be reduced. With this, the ratio of the reactive current. WC to the total current TC decreases, improving the ratio of the main current MC to the total current TC. Accordingly, the blue light-emitting element 6B according to the present embodiment improves in external quantum efficiency and improves in luminous efficiency.

In particular, the blue light-emitting layer 14B included in the blue light-emitting element 6B according to the present embodiment includes the insulating material 28 filled between the blue quantum dots 26B. Therefore, the blue light-emitting layer 14B according to the present embodiment can more efficiently reduce the reactive current WC flowing around the blue quantum dots 26B.

### Other Effects of Light-Emitting Element

Further, in the present embodiment, the gap 14DA of the blue light-emitting layer 14B is smaller than the gap 14DC. As a result, compared with a case in which the gap 14DA and the gap 14DC are equal, the efficiency of electron injection from the electron transport layer 16 into the blue quantum dots 26B is reduced. Therefore, the efficiency of hole injection from the hole transport layer 12B into the blue quantum dot 26B relatively increases compared with the efficiency of electron injection from the electron transport layer 16 to the blue quantum dot 26B.

In general, in an electric field carrier injection type light-emitting element including a quantum dot as a light-emitting material, the injection efficiency of electrons into the light-emitting layer is high compared with the injection efficiency of holes into the light-emitting layer, and an electron excess may occur in the light-emitting layer when the light-emitting element is driven. When an electron excess occurs in the light-emitting layer, the luminous efficiency of the light-emitting element may decrease and deactivation of the light-emitting material of the light-emitting layer may occur due to generation of Auger electrons, which is a deactivation process, or the like.

In the blue light-emitting element 6B according to the present embodiment, the injection efficiency of holes relative to the injection efficiency of electrons into the blue light-emitting layer 14B is high compared with that in the blue light-emitting element 6BA according to the comparative embodiment. As a result, the blue light-emitting element 6B reduces the electron excess in the blue light-emitting layer 14B and further improves the luminous efficiency.

In particular, the blue light-emitting layer 14B includes the insulating layer 24 that includes the insulating material 28 without including the blue quantum dot 26B or the ligand 30 on the cathode 18 side of the blue quantum dot layer 22B. Therefore, the blue light-emitting element 6B can more simply and reliably form a structure in which the gap 14DA is smaller than the gap 14DC.

Further, at least one of the blue quantum dot 26B or the ligand 30 positioned in the end face portion 14BA on the end face 14EA side of the blue light-emitting element 6B is in contact with the hole transport layer 12B. On the other hand, at least one of the blue quantum dot 26B or the ligand 30 positioned in the end face portion 143C on the end face 14EC side of the blue light-emitting element 6B is separated from the electron transport layer 16 by the insulating layer 24. Therefore, the blue light-emitting element 6B further reduces the injection of electrons from the electron transport layer 16 into the blue quantum dot 26B via the ligand 30.

In the present embodiment, the carrier mobility of the insulating material 28 is less than 10⁻⁶ cm²/V·sec, for example. For example, the carrier mobility of an organic material typically used for the ligand 30 is about 10⁻⁶ cm²/V·sec. Therefore, according to the configuration described above, the insulating material 28 achieves a lower mobility than the ligand 30, and efficiently reduces the generation of the reactive current WC in the blue light-emitting layer 14B.

In the present embodiment, the insulating material 28 has a light transmittance of 80% or greater in the visible light region, for example. With the configuration described above, the insulating material 28 is less likely to block light from the blue quantum dot 26B. Accordingly, according to the configuration described above, the insulating material 28 suppresses a reduction in light extraction efficiency from the blue light-emitting element 6B.

In the present embodiment, a thickness 24D of the insulating layer 24 is from 2 nm to 5 nm, for example. When the thickness 24D is 2 nm or greater, the insulating layer 24 can be more easily and reliably formed as a continuous film. When the thickness 24D is 5 nm or less, electrons are injected from the electron transport layer 16 into the blue quantum dot layer 22B by the tunneling of the electrons in the insulating layer 24. Therefore, with the thickness 24D being 5 nm or less, the insulating layer 24 suppresses a rise in the overall resistance value of the blue light-emitting element 6B.

Each of the red light-emitting element 6R and the green light-emitting element 6G has the same configuration as that of the blue light-emitting element 6B except for the type of quantum dot included in the light-emitting layer. Accordingly, each of the red light-emitting element 6R and the green light-emitting element 6G has the same effect as that of the blue light-emitting element 6B.

The display device 2 including, on a subpixel-by-subpixel basis, the red light-emitting element 6R, the green light-emitting element 6G, and the blue light-emitting element 6B with further improved luminous efficiency further reduces power consumption. Furthermore, in the display device 2, to obtain the same light emission intensity from each light-emitting element, the voltage applied to each light-emitting element can be reduced, and the lifetime of each light-emitting element is further improved.

### Method for Manufacturing Display Device

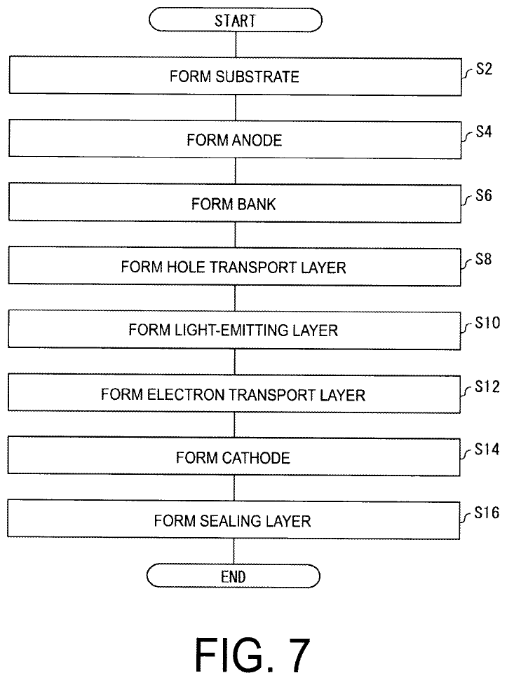

A method for manufacturing the display device 2 according to the present embodiment will now be described with reference to FIG. 7. FIG. 7 is a flowchart for describing the method for manufacturing the display device 2 according to the present embodiment.

In the method for manufacturing the display device 2 according to the present embodiment, first, the substrate 4 is formed (step S2). The substrate 4 may be formed by, for example, forming, on a rigid glass substrate, a film base material and TFTs on the film base material, and then peeling the glass substrate from the film base material. The peeling of the glass substrate described above may be executed after formation of the light-emitting element layer 6 and the sealing layer S described below. Alternatively, the substrate 4 may be formed by, for example, forming the TFTs directly on a rigid glass substrate.

Next, the anode 10 is formed on the substrate 4 (step S4). The anode 10 may be formed by, for example, forming a thin film of a metal material by sputtering or the like, and then patterning the thin film by dry etching or wet etching using a photoresist. Thus, the anode 10R, the anode 10G, and the anode 10B formed into island shapes on a subpixel-by-subpixel basis on the substrate 4 are obtained.

Next, the bank 20 is formed (step S6). In step S6, the bank 20 is formed by photolithography of a positive-working photosensitive resin. Specifically, for example, a positive-working photosensitive resin serving as a material of the bank 20 is applied to the upper faces of the substrate 4 and the anode 10. Next, a photomask having a light-transmitting portion at a position corresponding to each subpixel is placed above the applied photosensitive resin, and the photosensitive resin is irradiated with ultraviolet light or the like through the photomask. Then, the photosensitive resin irradiated with the ultraviolet light is cleaned with an appropriate developing solution. Thus, the bank 20 is formed between the positions corresponding to the subpixels on the substrate 4.

In general, as a distance between the photomask and an exposure target increases, an exposure area and an exposure intensity of the photomask in plan view tend to decrease. For this reason, when formed by photolithography using a positive-working photosensitive resin, the bank 20 is formed gradually smaller upwardly from the substrate 4 side. Accordingly, in step S6, the bank 20 is formed by applying, exposing, and developing the positive-working photosensitive resin, making it possible to form the bank 20 having the side surface 20S that is a forwardly tapered face.

Next, the hole transport layer 12 is formed (step S8). The hole transport layer 12 may be formed by, for example, applying a material having hole transport properties and then patterning the thin film by dry etching or wet etching using a photoresist. As a result, the hole transport layer 12R, the hole transport layer 12G, and the hole transport layer 123 formed into island shapes on the anode 10 on a subpixel-by-subpixel basis are obtained.

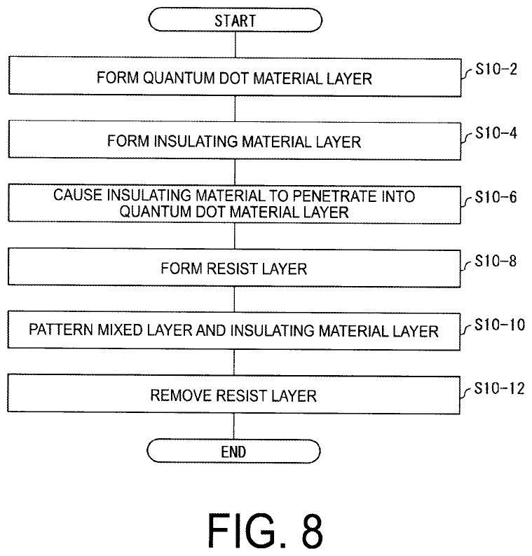

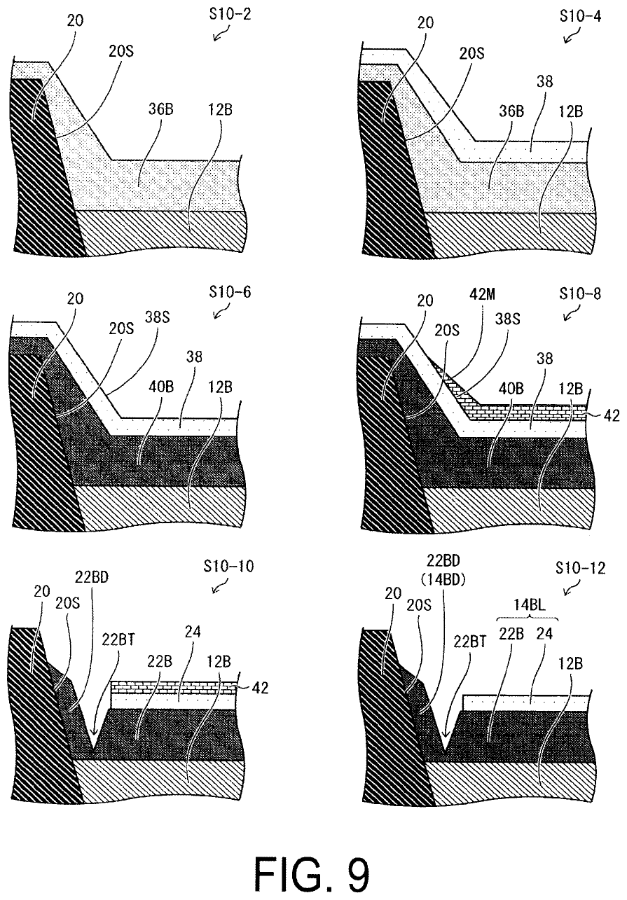

Method for Forming Light-Emitting Layer Next, the light-emitting layer 14 is formed (step S10). A method for forming the light-emitting layer 14 will now be further described in more detail with reference to FIG. 8 and FIG. 9. Hereinafter, the method for forming the light-emitting layer 14 in each embodiment including the present embodiment will be described using the method for forming the blue light-emitting layer 14B as a representative. FIG. 8 is a flowchart for describing the method for forming the light-emitting layer 14 according to the present embodiment. FIG. 9 illustrates process cross-sectional views of the vicinity of the side surface 20S of the bank 20 positioned in the blue subpixel SPB in the process of forming the light-emitting layer 14 according to the present embodiment. Note that each process cross-sectional view illustrated in the present specification including FIG. 9 illustrates a cross section at a position corresponding to the cross section illustrated in FIG. 4, unless otherwise specified.

First, a material including the blue quantum dots 26B is formed into a film on the entire surface of an upper layer overlying the hole transport layer 12B and the bank 20 to form a blue quantum dot material layer 36B (step S10-2). In other words, in step S10-2, the blue quantum dot material layer 36B is formed not only for the blue subpixel SPB but also for the red subpixel SPR and the green subpixel SPG. Therefore, the blue quantum dot material layer 36B is also formed on the side surface 20S of the bank 20.

The blue quantum dot material layer 36B may be formed by applying a solution including the blue quantum dots 26B using an application method using a coater or the like. The solution may include the blue quantum dots 26B, a solvent in which the blue quantum dots 26B are dispersed, and the ligands 30 for improving the dispersibility of the blue quantum dots 26B in the solvent.

Next, a material including the insulating material 28 is formed into a film on the blue quantum dot material layer 36B, thereby forming an insulating material layer 38 (step S10-4). The insulating material layer 38 may be formed by applying a solution including the insulating material 28 using an application method using a coater, for example. Note that the insulating material layer 38 is formed on an entire upper face of the blue quantum dot material layer 36B. Therefore, on an upper face of the insulating material layer 38, an inclined face 38S reflecting the inclination of the side surface 20S of the bank 20 is formed around the blue subpixel SPB.

The insulating material 28 may include an amorphous material, for example. In this case, the insulating material layer 38 can be formed by diluting the insulating material 28 with an appropriate solvent and applying the diluted solution. Further, with the insulating material 28 including an amorphous material, it is possible to form a stable layer including the insulating material 28 by applying a heat treatment or the like to the insulating material layer 38 and curing the amorphous material included in the insulating material 28 in a post-process.

For example, the insulating material 28 may include a glass-based material including spin-on-glass (SOG). In this case, the solution including the insulating material 28 may include, as a solvent, an ether-based solvent including diethyl ether, dioxolane, dioxane, tetrahydrofuran, or the like.

Further, for example, the insulating material 28 may include a tetrafluoroethylene-based material including polytetrafluoroethylene (PTFE; CYTOP). In this case, the solution including the insulating material 28 may include, as a solvent, a perfluoro-based solvent including a fluorous alcohol, a fluorous ether, a fluorous hexane, or the like.

Alternatively, for example, the insulating material 28 may include a silicone-based material including dimethyl silicone. In this case, the solution including the insulating material 28 may include, as a solvent, a hydrocarbon-based solvent including toluene, xylene, or the like.

According to the configuration described above, the insulating material 28 can be dissolved in an appropriate solvent, making it possible to more easily form the insulating material layer 38. Note that the insulating material 28 may include a plurality of materials among the materials described above.

Next, the insulating material layer 38 positioned on the blue quantum dot material layer 36B is maintained, causing a portion of the insulating material 28 included in the insulating material layer 38 to penetrate into the blue quantum dot material layer 36B (step S10-6). Step S10-6 may be executed by allowing the substrate 4 to stand for about 30 minutes following step S10-4. As a result, a mixed layer 40B including the blue quantum dots 26B and the insulating material 28 is formed immediately below the insulating material layer 38.

Next, the resist layer 42 is formed in an upper layer overlying the insulating material layer 38 (step S10-8). Here, the resist layer 42 is formed into an island shape at a position overlapping, in plan view of the substrate 4, the blue subpixel SPB in which the blue light-emitting layer 14B is formed. The resist layer 42 may be formed by, for example, applying a material of the resist layer including a photosensitive resin and patterning the material by photolithography.

When the resist layer 42 is formed by applying a material and patterning the material as described above, the material of the resist layer 42 is also formed into a film on the inclined face 38S of the insulating material layer 38 that is formed along the side surface 20S of the bank 20. Further, with the material of the resist layer 42 thus formed being patterned, the material of the resist layer 42 also remains at a position adjacent to the inclined face 38S.

Here, a portion of the resist layer 42 that is formed at a position adjacent to the inclined face 38S creeps up the inclined face 38S due to the meniscus effect. Therefore, in step S10-8, an outer edge portion 42M of the resist layer 42 is thinly formed on the inclined face 38S as well. Accordingly, after execution of step S10-8, the insulating material layer 38 and the mixed layer 40B are covered with the outer edge portion 42M of the resist layer 42 at a position overlapping the side surface 20S of the bank 20 in plan view of the substrate 4, the outer edge portion 42M being relatively thin.

Next, the insulating material layer 38 and the mixed layer 40B are etched by an appropriate etching method to pattern the insulating material layer 38 and the mixed layer 40B (step S10-10). The resist layer 42 includes a material resistant to the etching of the insulating material layer 38 and the mixed layer 40B. Therefore, in step S10-10, only the insulating material layer 38 and the mixed layer 40B in a lower layer thereof that are exposed from the resist layer 42 are etched in plan view of the substrate 4. As a result, the mixed layer 40B having an island shape and the insulating material layer 38 are formed for each blue subpixel SPB, and become the blue quantum dot layer 22B and the insulating layer 24, respectively.

The insulating material layer 38 and the mixed layer 40B are etched by dry etching or wet etching. For example, the insulating material layer 38 and the mixed layer 40B are etched by removing the insulating material layer 38 and the mixed layer 40B exposed from the resist layer 42 by an appropriate etching material.

For example, when the insulating material 28 includes SOG, the insulating material layer 38 can be removed by an etching material including hydrofluoric acid, buffered hydrofluoric acid, or the like. Further, when the insulating material 28 includes PTFE or dimethyl silicone, the insulating material layer 38 can be removed by ashing using O₂ or O₂ plasma, reactive ion etching (RIE), or the like. With the configuration described above, the insulating material layer 38 and the mixed layer 40B can be etched more reliably.

When step S10-8 is completed, the resist layer 42 is thinly formed as the outer edge portion 42M also on the inclined face 38S of the insulating material layer 38 positioned around the blue subpixel SPB. Therefore, in plan view of the substrate 4, the insulating material layer 38 and the mixed layer 40B at the position overlapping the outer edge portion 42M are etched more weakly than the etching of the insulating material layer 38 and the mixed layer 40B exposed from the resist layer 42.

Accordingly, by execution of step S10-10, a portion of the mixed layer 40B remains on the side surface 20S of the bank 20 without being etched. However, in plan view of the substrate 4, by the etching of the insulating material layer 38 and the mixed layer 40B at a position overlapping the outer edge portion 42M, the insulating material layer 38 at that position is removed, and the mixed layer 40B is exposed to the etching material.

In particular, the etching in step S10-10 is executed by dry etching or wet etching. In this case, the blue quantum dots 26B remaining on the side surface 20S of the bank 20 and included in the mixed layer 40B exposed to the etching material are deteriorated and deactivated by oxidation or the like. Therefore, when step S10-10 is completed, the deactivation layer 22BD that is thinner than the blue quantum dot layer 22B and includes the deactivated blue quantum dots 26B is formed on the side surface 20S of the bank 20. Note that, upon completion of step S10-10, the thin film portion 22BT thinner than the surrounding area may be formed at a boundary between the blue quantum dot layer 22B and the deactivation layer 22BD.

Next, the resist layer 42 is removed from above the insulating material layer 38 by cleaning the resist layer 42 that remains with an appropriate remover (step S10-12). Thus, the main light-emitting portion 14BL, including the blue quantum dot layer 22B and the insulating layer 24, and the outer edge portion 14BD, including the deactivation layer 22BD, are obtained.

With the above, the process of forming the blue light-emitting layer 14B is completed. Note that, in step S10-6 and thereafter, the solvent in the insulating material layer 38 may be volatilized and the amorphous material included in the insulating material 28 may be cured by heat treatment of the insulating material layer 38 or the like. In this case, a compound derived from the solvent included in the insulating material layer 38 may remain as a second compound in the blue light-emitting layer 14B.

The red light-emitting layer 14R and the green light-emitting layer 14G may be formed by partially changing the process of forming the blue light-emitting layer 14B described above, and executing the changed process. For example, in the process of forming the red light-emitting layer 14R and the green light-emitting layer 14G, the blue quantum dots 26B included in the blue quantum dot material layer 36B in the process of forming the blue light-emitting layer 14B are changed to red quantum dots and green quantum dots, respectively. Further, in the process of forming the red light-emitting layer 14R and the green light-emitting layer 14G, the position where the resist layer 42 is formed in step S10-8 described above is changed to positions overlapping the red subpixel SPR and the green subpixel SPG, respectively, in plan view of the substrate 4. With the above, the process of forming the light-emitting layer 14 according to the present embodiment can be executed.

### Method for Forming Remaining Portion

Following the step of forming the light-emitting layer 14, the second electron transport layer 16 is formed (step S12). The electron transport layer 16 may be formed in common to the subpixels by applying a material having electron transport properties, for example. Next, the cathode 18 is formed on the electron transport layer 16 (step S14). The cathode 18 may be formed by, for example, forming a thin film of a metal material in common to the subpixels by sputtering. With the above, formation of the light-emitting element layer 6 is completed.

Next, the sealing layer 8 is formed (step S16). In a case in which the sealing layer 8 includes an organic sealing film, the organic sealing film may be formed by applying an organic sealing material. Further, in a case in which the sealing layer 8 includes an inorganic sealing film, the inorganic sealing film may be formed by CVD or the like. Thus, the sealing layer 8 that seals the light-emitting element layer 6 is formed, and the manufacture of the display device 2 is completed.

### Effects of Manufacturing Method

The method for forming the blue light-emitting element 6B according to the present embodiment includes, for example, a penetration process of forming the insulating material layer 38 in an upper layer overlying the blue quantum dot material layer 36B and causing a portion of the insulating material 28 in the insulating material layer 38 to penetrate into the blue quantum dot material layer 36B. In the penetration process, the insulating material 28 penetrated into the blue quantum dot material layer 36B is a portion of the insulating material 28 in the insulating material layer 38, and thus the insulating material layer 38 remains in an upper layer overlying the blue quantum dot material layer 36B. Accordingly, by the method for forming the blue light-emitting element 6B described above, the blue light-emitting element 6B including the layering of the blue quantum dot layer 22B and the insulating layer 24 can be obtained. Therefore, by the formation method described above, the blue light-emitting element 6B in which the gap 14DA is smaller than the gap 14DC can be easily formed.

Further, due to the penetration process described above, the method for manufacturing the display device 2 according to the present embodiment does not require a process of separately applying a material obtained by mixing the blue quantum dots 26B and the insulating material 28. This makes it possible to select a more appropriate solvent for dispersing the blue quantum dots 26B as the material of the blue quantum dot material layer 36B.

Furthermore, by the penetration process described above, it is possible to easily form the mixed layer 40B in which the density of the insulating material 28 gradually increases from the anode 10 side to the cathode 18 side. The blue light-emitting element 6B including the blue quantum dot layer 22B manufactured by the manufacturing method described above can more efficiently improve the efficiency of hole injection from the anode 10 side relative to the efficiency of electron injection from the cathode 18 side.

For example, assume for the moment that the blue light-emitting layer 14B is divided into two portions, a portion on the anode 10 side and a portion on the cathode 18 side, from a center position of the blue light-emitting element 6B in a layering direction. By the method for forming the blue light-emitting layer 14B including the penetration process described above, the blue light-emitting layer 14B can be formed with an average density of the insulating material 28 being higher in the portion on the cathode 18 side than in the portion on the anode 10 side, from the above-described center position of the blue light-emitting layer 14B.

Further, assume for the moment that the blue light-emitting layer 14B is equally divided into three portions, a first portion, a second portion positioned closer to the cathode 18 than the first portion, and a third portion positioned closer to the cathode 18 than the second portion, in the layering direction of the blue light-emitting element 6B from the anode 10 side. In particular, the first portion includes the end face 14EA and the third portion includes the end face 141E. By the method for forming the blue light-emitting layer 14B including the penetration process described above, the blue light-emitting layer 14B can be formed with an average density of the insulating material 28 increasing in the order of the first portion, the second portion, and the third portion.

Alternatively, by the method for forming the blue light-emitting layer 14B including the penetration process described above, the blue light-emitting layer 14B can be formed with the average density of the insulating material 28 gradually increasing from the anode 10 side to the cathode 18 side.

For example, assume for the moment a cross section obtained by cutting the blue light-emitting layer 14B at an arbitrary cross section in the normal direction of any surface of the blue light-emitting layer 14B. In this case, the quantity of the insulating material 28 per unit surface area on the cut surface is calculated. Thus, a magnitude relationship of the average density of the insulating material 28 included in the blue light-emitting layer 14B may be measured by comparing the quantity of the insulating material 28 per unit surface area.

Further, in a case in which the measurement described above is difficult, a time-of-flight secondary ion mass spectrometry (TOF-SIMS) technique may be used as a technique for directly observing molecules of the insulating material 28 and a concentration of the molecules of the insulating material 28. The TOF-SIMS technique is a method of sputtering a minute region, on the order of micrometers, on one side of a measurement target, and determining a mass of the substance liberated by a time of flight of the substance. A type of the substance can be identified by comparing the mass detected by the technique with a database. By using the TOF-SIMS technique, it is possible to directly quantify the type and the mass of the substance from the order of atoms to the order of macromolecules.

In addition to the method described above, the molecules of the insulating material 28 and the concentration of the molecules of the insulating material 28 can be observed by using a gas chromatography mass spectrometry (GCMS) technique. The GCMS technique is a method for qualitatively and quantitatively analyzing an object subject to analysis by gas chromatography and mass spectrometry. Alternatively, in a case in which measurement by the method described above is difficult, an energy dispersive X-ray spectroscopy (EDX) technique may be used.

Comparison of measurement results in a method among the methods described above that does not specify the comparison method of the measurement results may be implemented by a method such as follows. For example, on a cut face obtained by cutting the blue light-emitting layer 14B at any cross section, a detection amount of a specific element included in the composition of the insulating material 28 in a certain measurement range is measured. Further, for the comparison, the measurement described above is implemented as appropriate on any line segment parallel to the normal line of the surface of the blue light-emitting layer 14B on the cut face described above. Accordingly, the magnitude relationship of the average density of the insulating material 28 included in the blue light-emitting layer 14B may be determined by comparing the magnitude relationship of the average detection amount on the line segment within a range of comparison as appropriate. Note that, although the measurement methods described above are preferred, when measurement is difficult by the measurement methods described above, the measurement may be performed by another method.

The insulating material layer 38 formed in step S10-4 according to the present embodiment may include the insulating material 28, including a tetrafluoroethylene-based material, and a perfluoro-based solvent. In this case, the blue quantum dot material layer 36B formed in step S10-2 according to the present embodiment may include the ligands 30 soluble in the perfluoro-based solvent. In this case, the mixing of the blue quantum dot material layer 36B, which is a colloidal solution including the blue quantum dots 26B, and the insulating material layer 38 including the perfluoro-based solvent is promoted. Therefore, with the configuration described above, it is possible to more effectively execute the penetration process in step S10-6 according to the present embodiment.

In step S10-8 according to the present embodiment, the insulating material layer 38 is formed in an upper layer overlying the mixed layer 40B. The insulating material layer 38 can therefore protect the mixed layer 40B from the developing solution used for patterning the resist layer 42, thereby reducing deterioration of the blue quantum dots 263.

Further, in step S10-10 according to the present embodiment, the insulating material layer 38 and the mixed layer 40B are patterned by dry etching or wet etching. Therefore, by step S10-10, at the position covered with the outer edge portion 42M of the resist layer 42, the deactivation layer 22BD, including the deactivated blue quantum dots 26B, and the outer edge portion 14BD including the deactivation layer 22BD are formed.

Therefore, the luminous efficiency of the outer edge portion 14BD, which is included in the blue light-emitting element 6B formed by the formation method described above, is extremely low because the included blue quantum dots 26B are deactivated. Accordingly, by forming the blue light-emitting element 6B by the formation method described above, abnormal light emission by the outer edge portion 14BD can be reduced.

Therefore, the blue light-emitting element 6B can make the carriers injected into the blue light-emitting layer 14B efficiently contribute to light emission of the main light-emitting portion 14BL, thereby improving the luminous efficiency of the main light-emitting portion 14BL. Further, the blue light-emitting element 6B includes, at the outer edge of the main light-emitting portion 14BL, the outer edge portion 14BD having a low luminous efficiency. Thus, the blue light-emitting element 6B can reduce the light emission intensity at or near the boundary with the other light-emitting elements. As a result, the display device 2 including the blue light-emitting element 6B can reduce color mixing between subpixels, improving the display quality.

Furthermore, in step S10-12 according to the present embodiment, the insulating layer 24 is formed in an upper layer overlying the blue quantum dot layer 22B. The insulating layer 24 can therefore protect the blue quantum dot layer 22B from the remover used for removing the resist layer 42, thereby reducing deterioration of the blue quantum dot layer 26B.

Note that, after completion of step S10-10 according to the present embodiment, a portion of the blue quantum dot layer 22B that is patterned may creep up an upper face of the deactivation layer 22BD due to the meniscus effect. In this case as well, with the deactivation layer 22BD including the deactivated blue quantum dots 26B formed in the outer edge portion 14BD, the luminous efficiency of the outer edge portion 14BD is still sufficiently lower than that of the main light-emitting portion 14BL.

The methods for forming the red light-emitting element 6R and the green light-emitting element 6G according to the present embodiment can be executed by simply changing the material of the quantum dots and the formation position of the light-emitting layer 14 in the method for forming the blue light-emitting element 6B. Accordingly, the methods for forming the red light-emitting element 6R and the green light-emitting element 6G according to the present embodiment also achieve the same effects as those of the method for forming the blue light-emitting element 6B.

### Second Embodiment

### Quantum Dot Layer not Including Insulating Material

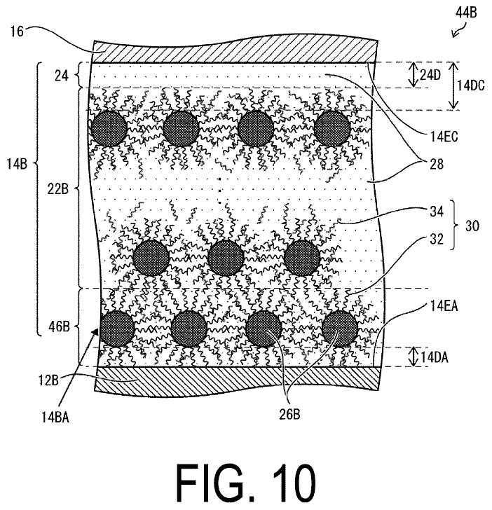

FIG. 10 is an enlarged schematic view illustrating a partial region of a schematic cross section of the display device 2 according to the present embodiment, and is an enlarged view of a position corresponding to the enlarged schematic view of the display device 2 illustrated in FIG. 1. As compared with the display device 2 according to the previous embodiment, the display device 2 according to the present embodiment includes a red light-emitting element 44R, a green light-emitting element 44G, and a blue light-emitting element 44B instead of the red light-emitting element 6R, the green light-emitting element 6G, and the blue light-emitting element 6B, respectively. Otherwise, the display device 2 according to the present embodiment has the same configuration as that of the display device 2 according to the previous embodiment.

In the blue light-emitting element 44B according to the present embodiment, as compared with the blue light-emitting element 6B according to the previous embodiment, the blue light-emitting layer 14B further includes a blue quantum dot layer 46B including the blue quantum dots 26B and the ligands 30 on the anode 10 side. In particular, among the materials included in the blue quantum dot layer 22B, the blue quantum dot layer 46B does not include the insulating material 28.

Note that the blue quantum dot layer 46B forms the end face 14EA of the blue light-emitting layer 14B on the anode 10 side, and is in contact with the hole transport layer 12B. Therefore, the end face portion 14BA in the present embodiment refers to an area from the end face 14EA to a portion where, of the blue quantum dots 26B included in the blue quantum dot layer 46B, 20 blue quantum dots 26B closest to the end face 14EA are positioned.

Otherwise, the blue light-emitting element 44B according to the present embodiment has the same configuration as that of the blue light-emitting element 63 according to the previous embodiment. For example, in the present embodiment, the blue quantum dot layer 22B includes the insulating material 28 between the blue quantum dots 26B. Further, in the present embodiment, the gap 14DA is smaller than the gap 14DC.

As described above, the blue light-emitting element 44B reduces the occurrence of a reactive current and the occurrence of electron excess in the blue light-emitting layer 14B for the same reasons as those described in the previous embodiment. Therefore, the blue light-emitting element 44B improves the luminous efficiency and extends the lifetime.

Further, the blue light-emitting element 44B includes the blue quantum dot layer 46B that does not include the insulating material 28 on the anode 10 side of the blue light-emitting layer 14B. In particular, the blue quantum dot layer 46B includes only the blue quantum dots 26B and the ligands 30 among the materials included in the blue quantum dot layer 223. As a result, the blue light-emitting element 44B can further improve the efficiency of hole injection from the anode 10 side via the ligands 30 and the like while realizing a reduction in the reactive current and a reduction in electron excess.

Furthermore, as compared with the blue light-emitting element 44B, the red light-emitting element 44R and the green light-emitting element 44G according to the present embodiment have the same configuration except for the luminescent color of the quantum dots included in the light-emitting layer 14. Accordingly, each of the red light-emitting element 44R and the green light-emitting element 44G has the same effect as that of the blue light-emitting element 44B.

### Mixed Layer Formation Process

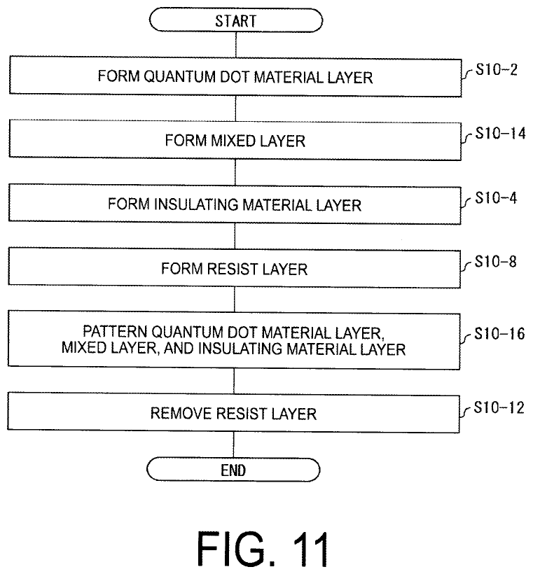

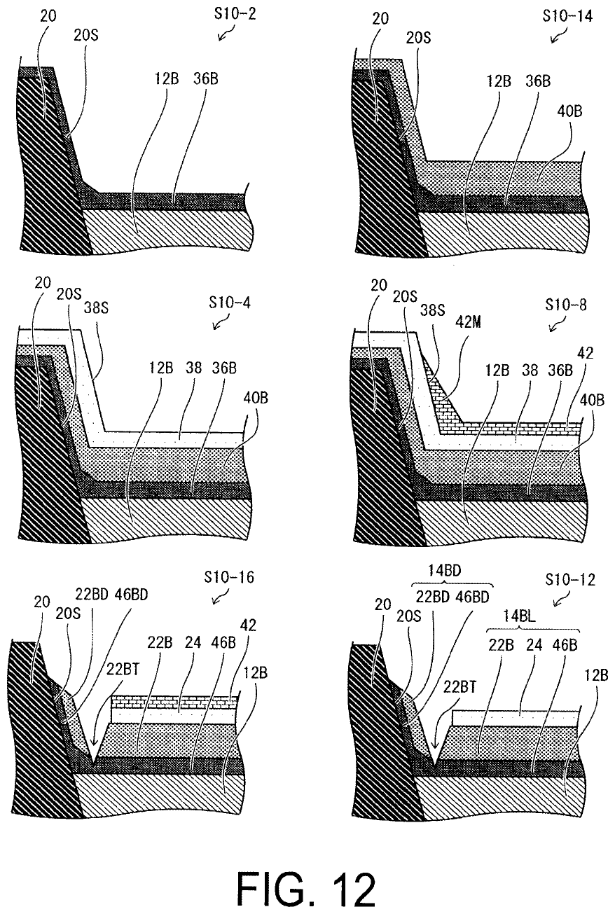

The display device 2 according to the present embodiment can be manufactured by the same method as the method for manufacturing the display device 2 according to the previous embodiment by changing only the formation process of the light-emitting layer. The method for forming the light-emitting layer 14 according to the present embodiment will now be described in more detail with reference to FIG. 11 and FIG. 12. FIG. 11 is a flowchart for describing the method for forming the light-emitting layer 14 according to the present embodiment. FIG. 12 illustrates process cross-sectional views of the vicinity of the side surface 20S of the bank 20 positioned in the blue subpixel SPB in the process of forming the light-emitting layer 14 according to the present embodiment.

In the process of forming the blue light-emitting layer 14B according to the present embodiment, first, the blue quantum dot material layer 36B is formed by the same technique as in step S10-2 according to the previous embodiment. Here, in step S10-2 according to the present embodiment, in consideration of the film thickness of the blue quantum dot layer 46B, the blue quantum dot material layer 36B may be formed thinner compared with step S10-2 according to the previous embodiment.

Next, the mixed layer 40B is formed on the blue quantum dot material layer 36B by applying a material obtained by mixing the blue quantum dots 26B and the insulating material 28 (step S10-14). The mixed layer 40B may further include the ligands 30 and may include a solvent in which the insulating material 28 is soluble.

Note that the mixed layer 40B according to the present embodiment may include the same material as that of the mixed layer 40B according to the previous embodiment. However, with the mixed layer 40B according to the present embodiment being formed from a solution obtained by mixing the blue quantum dots 26B and the insulating material 28, the density of the insulating material 28 is more uniform than that of the mixed layer 40B according to the previous embodiment.

Next, the insulating material layer 38 is formed on the mixed layer 40B by the same technique as that in step S10-4 according to the previous embodiment. In the present embodiment as well, on the upper face of the insulating material layer 38, the inclined face 38S reflecting the inclination of the side surface 20S of the bank 20 is formed around the blue subpixel SPB.

Next, the resist layer 42 is formed in an upper layer overlying the insulating material layer 38 for each blue subpixel SPB by the same technique as that in step S10-8 according to the previous embodiment. In the present embodiment as well, a portion of the resist layer 42 formed at a position adjacent to the inclined face 38S creeps up the inclined face 38S due to the meniscus effect. Accordingly, after execution of step S10-8, the insulating material layer 38 and the mixed layer 40B are covered with the outer edge portion 42M of the resist layer 42 at a position overlapping the side surface 20S of the bank 20 in plan view of the substrate 4, the outer edge portion 42M being relatively thin.

Next, the blue quantum dot material layer 36B, the insulating material layer 38, and the mixed layer 40B are etched by an appropriate etching method to pattern the blue quantum dot material layer 36B, the insulating material layer 38, and the mixed layer 40B (step S10-16). The blue quantum dot material layer 36B can be etched by an etching material that can etch the insulating material layer 38 and the mixed layer 40B. Accordingly, step S10-16 can be executed by the same method as that in step S10-10 according to the previous embodiment, except that the blue quantum dot material layer 36B is further patterned. As a result, the blue quantum dot material layer 36B, the mixed layer 40B, and the insulating material layer 38 having island shapes are formed for each blue subpixel SPB, and become the blue quantum dot layer 46B, the blue quantum dot layer 22B, and the insulating layer 24, respectively.

In the present embodiment as well, when step S10-8 is completed, the resist layer 42 is also thinly formed as the outer edge portion 42M on the inclined face 38S of the insulating material layer 38 positioned around the blue subpixel SPB. Thus, by execution of step S10-16, a portion of each of the blue quantum dot material layer 36B and the mixed layer 40B remains on the side surface 20S of the bank 20 without being etched. However, the blue quantum dot material layer 36B and the mixed layer 40B at this position are exposed to the etching material under the same circumstances as those described in the previous embodiment.

In particular, the etching in step S10-16 is executed by dry etching or wet etching. In this case, the blue quantum dots 26B remaining on the side surface 20S of the bank 20 and included in the blue quantum dot material layer 36B and the mixed layer 40B exposed to the etching material are deteriorated and deactivated by oxidation or the like. Therefore, when step S10-16 is completed, a deactivation layer 46BD and the deactivation layer 22BD are formed on the side surface 20S of the bank 20 in this order from the bank 20 side. Note that the deactivation layer 46BD is formed by deactivation of the blue quantum dots 26B of the blue quantum dot material layer 36B, and the deactivation layer 22BD is formed by deactivation of the blue quantum dots 26B of the mixed layer 40B.

Next, the resist layer 42 is removed from above the insulating material layer 38 by the same technique as that in step S10-12 according to the previous embodiment. Thus, the main light-emitting portion 14BL, including the blue quantum dot layer 46B, the blue quantum dot layer 22B, and the insulating layer 24, and the outer edge portion 14BD, including the deactivation layer 46BD and the deactivation layer 22BD, are obtained.

The red light-emitting layer 14R and the green light-emitting layer 14G may be formed by partially changing the process of forming the blue light-emitting layer 14B described above in accordance with the method described in the previous embodiment, and executing the changed process. With the above, the process of forming the light-emitting layer 14 according to the present embodiment can be executed.

In the formation method of the blue light-emitting element 6B according to the present embodiment, in step S10-14, the mixed layer 40B is formed from a solution obtained by mixing the blue quantum dots 26B and the insulating material 28. Therefore, according to the formation method, it is possible to form the blue quantum dot layer 22B in which the density of the insulating material 28 is more uniform, and form the blue light-emitting layer 14B in which the reactive current is reduced by enhanced stability.

Further, in the formation method described above, the blue quantum dot material layer 36B that does not include the insulating material 28 is formed in step S10-2. As a result, in the formation method, the blue quantum dot layer 46B that does not include the insulating material 28 can be more reliably formed on the anode 10 side of the blue light-emitting layer 14B. In addition, the formation method does not include a process of causing the insulating material 28 to penetrate into the blue quantum dot material layer 36B. As a result, in the present embodiment, the penetration process in the previous embodiment can be omitted, thereby further simplifying the formation method described above.

The mixed layer 40B formed in step S10-14 according to the present embodiment may include the insulating material 28 including a tetrafluoroethylene-based material, a perfluoro-based solvent, and the ligands 30 soluble in the perfluoro-based solvent. In this case, the colloidal mixture of the blue quantum dots 26B, the insulating material 28 soluble in a perfluoro-based solvent, and the ligands 30 similarly soluble in a perfluoro-based solvent is promoted. With the configuration described above, in step S10-14 according to the present embodiment, the mixing of the solution used for forming the mixed layer 40B is further promoted, making it possible to form the mixed layer 40B that is more uniform.

### Third Embodiment

Quantum Dot Layer with Reduced Excess Ligands

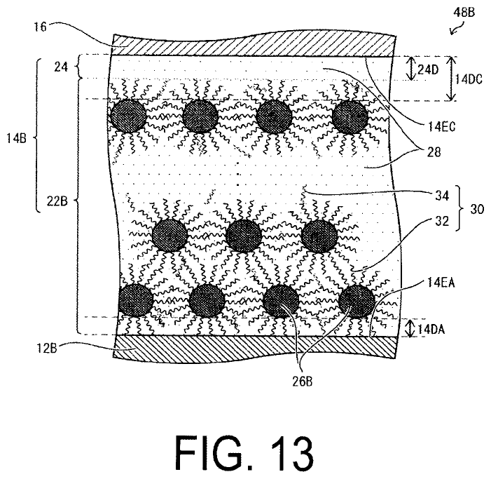

FIG. 13 is an enlarged schematic view illustrating a partial region of a schematic cross section of the display device 2 according to the present embodiment, and is an enlarged view of a position corresponding to the enlarged schematic view of the display device 2 illustrated in FIG. 1. As compared with the display device 2 according to the first embodiment, the display device 2 according to the present embodiment includes a red light-emitting element 48R, a green light-emitting element 48G, and a blue light-emitting element 48B instead of the red light-emitting element 6R, the green light-emitting element 6G, and the blue light-emitting element 6B, respectively. Otherwise, the display device 2 according to the present embodiment has the same configuration as that of the display device 2 according to the first embodiment.

The blue light-emitting element 48B according to the present embodiment, as compared with the blue light-emitting element 6B according to the first embodiment, has a low concentration of the excess ligands 34 among the ligands 30 included in the blue quantum dot layer 22B of the blue light-emitting layer 14B. Specifically, the number of the excess ligands 34 included in the blue quantum dot layer 22B according to the present embodiment is few compared with the number of the excess ligands 34 included in the blue quantum dot layer 22B according to the first embodiment. For example, in the present embodiment, a ratio of the excess ligands 34 included in the blue quantum dot layer 22B to the binding ligands 32 included in the blue quantum dot layer 22B is low. Otherwise, the blue light-emitting element 48B according to the present embodiment has the same configuration as that of the blue light-emitting element 6B according to the first embodiment.

The blue light-emitting element 48B reduces the occurrence of a reactive current and the occurrence of electron excess in the blue light-emitting layer 14B for the same reasons as those described in the first embodiment. Therefore, the blue light-emitting element 48B improves the luminous efficiency and extends the lifetime.

Further, the concentration of the excess ligands 34 included in the blue quantum dot layer 22B according to the present embodiment is lower than the concentration of the excess ligands 34 included in the blue quantum dot layer 22B according to each of the embodiments described above. The excess ligands 34 have a long average value of a gap to the closest blue quantum dot 26B compared with that of the binding ligands 32. For this reason, as compared with the binding ligands 32, the excess ligands 34 more readily contribute to the transport of carriers between the blue quantum dots 26B than the injection of carriers into the blue quantum dots 26B, and thus more strongly contribute to the generation of reactive current. Accordingly, the blue light-emitting layer 14B of the blue light-emitting element 48B reduces the concentration of the excess ligands 34 that mainly contribute to the generation of reactive current, and more effectively reduces the generation of reactive current in the blue light-emitting element 48B.

Herein, n is the total number of carbon atoms, halogen atoms, group III atoms, group IV atoms, group V atoms, group VI atoms, and hydrogen chains of the excess ligands 34. In this case, a ratio of the number of the excess ligands 34 to the total number of the ligands 30 may be 1/(2n) or less. In this case, the blue light-emitting layer 14B more effectively reduces the generation of reactive current in the blue light-emitting element 48B. Further, when the ratio of the number of the excess ligands 34 to the total number of the ligands 30 is 3/(10n) or less, the blue light-emitting layer 14B more effectively reduces the generation of reactive current in the blue light-emitting element 48B.

The ratio of the number of the excess ligands 34 to the number of the ligands 30 in the blue light-emitting layer 14B may be measured by using, for example, a diffusion ordered spectroscopy (DOSY) technique. The DOSY technique is a composition analysis method of mapping a molecular weight of each molecule and a diffusion coefficient relative to a magnetic field gradient for a mixture including a plurality of types of molecules.

When the DOSY technique is applied to the ligands 30, the measured value of the diffusion coefficient relative to the molecular weight of the excess ligands 34 is higher than the measured value of the diffusion coefficient relative to the molecular weight of the binding ligands 32. Accordingly, a concentration ratio between the binding ligands 32 and the excess ligands 34 can be calculated by calculating, for the blue light-emitting layer 14B, an integrated intensity of a peak on a molecular weight—diffusion constant map obtained by mapping based on the DOSY technique.

Alternatively, the ratio of the number of the excess ligands 34 to the number of the ligands 30 in the blue light-emitting layer 14B may be measured by using, for example, a thermal desorption—gas chromatograph/mass spectrometer (TD-GC/MS) technique. The TD-GC/MS technique is a composition analysis method of locally heated a material surface by a probe including a heat source, adsorbing a volatilized component by an adsorbent, and performing gas phase chromatography and mass spectrometry on the component.

When the TD-GC/MS technique is applied to the ligands 30, the measured value of the volatilization temperature relative to the molecular weight of the excess ligands 34 is lower than the measured value of the volatilization temperature relative to the molecular weight of the binding ligands 32. This is accompanied by a decrease in the volatilization temperature of the excess ligands 34 by a temperature corresponding to the energy consumed for coordination bond formation of the binding ligands 32. Accordingly, the concentration ratio between the binding ligands 32 and the excess ligands 34 can be calculated by individually performing mass spectrometry on the binding ligands 32 and the excess ligands 34 from the difference in the volatilization temperature relative to the molecular weight obtained by the TD-GC/MS technique with respect to the blue light-emitting layer 14B.

By the analysis method described above, the ratio of the number of the excess ligands 34 to the total number of the ligands 30 in the blue light-emitting layer 14B can be calculated from the concentration ratio between the binding ligands 32 and the excess ligands 34. Note that, in a case in which the analysis method described above is applied to the display device 2, the light-emitting layer 14 included in a portion of the light-emitting elements may be analyzed and the measurement result may be applied to the light-emitting layer 14 included in each light-emitting element. In particular, in the TD-GC/MS technique, local heating by a probe is possible, and thus analysis of the light-emitting layer 14 included in a single light-emitting element is possible.

### Comparison of Characteristics of Light-Emitting Elements

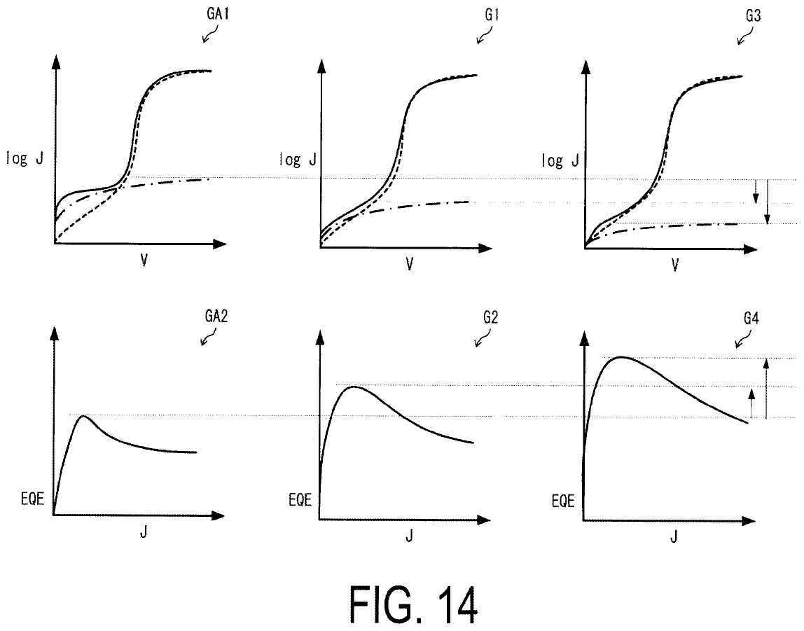

With reference to FIG. 14, the respective characteristics of the blue light-emitting element 6BA according to the comparative embodiment, the blue light-emitting element 6B according to the first embodiment, and the blue light-emitting element 48B according to the present embodiment will be compared and evaluated. The graphs illustrated in FIG. 14 are graphs showing characteristics of the blue light-emitting element according to each embodiment.

The characteristics of the blue light-emitting element 6BA according to the comparative embodiment are illustrated in graph GA1 and graph GA2. The characteristics of the blue light-emitting element 6B according to the first embodiment are illustrated in graph G1 and graph G2. The characteristics of the blue light-emitting element 48B according to the present embodiment are illustrated in graph G3 and graph G4.

The graph GA1, the graph G1, and the graph G3 each show the applied voltage—current characteristics of the blue light-emitting element according to respective embodiments, with the horizontal axis representing the applied voltage and the vertical axis representing the logarithm of the current value. In the graph GA1, the graph G1, and the graph G3, solid lines indicate measured values of the characteristics of the blue light-emitting elements according to the respective embodiments, and dashed lines indicate the characteristics of an ideal diode.

The difference between the characteristics of an ideal diode and the characteristics of an actual light-emitting element occurs due to the generation of a reactive current that does not contribute to light emission in the light-emitting element. In other words, the difference between the ideal current value of the diode and the actual current value of the light-emitting element indicates the magnitude of the reactive current generated in the light-emitting element.

In the graph GA1, the graph G1, and the graph G3, the difference between the current value of the ideal diode and the current value of the blue light-emitting element according to each embodiment is indicated by a dashed-dotted line. In other words, in the graph GA1, the graph G1, and the graph (G3, the dashed-dotted line indicates the value of the reactive current generated in the blue light-emitting element according to each embodiment.

In FIG. 14, the values of the reactive current at the applied voltages at which the current value of the reactive current is substantially saturated in the graph GA1, the graph G1, and the graph G3 are compared by dotted lines. As is clear from the comparison between the graph GA1 and the graph G1, the reactive current of the blue light-emitting element 6B according to the first embodiment is reduced compared with that of the blue light-emitting element 6BA according to the comparative embodiment. Furthermore, as is clear from the comparison between the graph G1 and the graph G3, the reactive current of the blue light-emitting element 48B according to the present embodiment is further reduced as compared with that of the blue light-emitting element 6B according to the first embodiment.

The graph GA2, the graph G2, and the graph G4 respectively show values of external quantum efficiencies with respect to values of currents flowing through the blue light-emitting elements according to the respective embodiments, with the horizontal axis representing the current values and the vertical axis representing the external quantum efficiencies. In FIG. 14, maximum values of the external quantum efficiencies in the graph GA2, the graph G2, and the graph 64 are compared by dotted lines. In general, the external quantum efficiency of a light-emitting element is proportional to the luminous efficiency of the light-emitting element.

As is clear from the comparison between the graph GA2 and the graph 62, the blue light-emitting element 6B according to the first embodiment has a high maximum external quantum efficiency compared with that of the blue light-emitting element 6BA according to the comparative embodiment. Furthermore, as is clear from the comparison between the graph G2 and the graph G4, the blue light-emitting element 48B according to the present embodiment has an even higher maximum external quantum efficiency compared with that of the blue light-emitting element 6B according to the first embodiment.

As described above, the blue light-emitting element 63 according to the first embodiment reduces the reactive current and improves the luminous efficiency as compared with the blue light-emitting element 6BA according to the comparative embodiment. Furthermore, the blue light-emitting element 48B according to the present embodiment further reduces the reactive current and further improves the luminous efficiency as compared with the blue light-emitting element 6B according to the first embodiment.

Note that the red light-emitting element 48R and the green light-emitting element 48G according to the present embodiment have the same configuration as that of the blue light-emitting element 48B, except for the luminescent color of the quantum dots included in the light-emitting layer 14. Accordingly, each of the red light-emitting element 48R and the green light-emitting element 48G has the same effect as that of the blue light-emitting element 48B.

### Method for Removing Excess Ligands

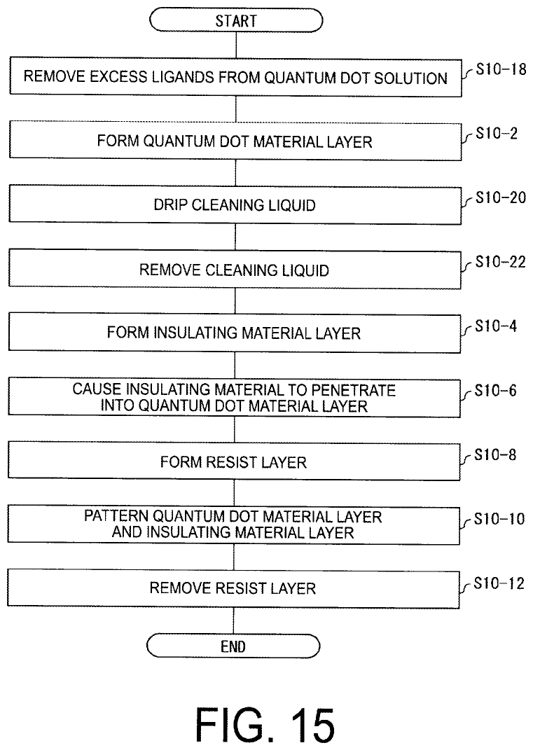

The display device 2 according to the present embodiment can be manufactured by a manufacturing method obtained by changing only the process of forming the light-emitting layer in the method for manufacturing the display device 2 according to the first embodiment. The method for forming the light-emitting layer 14 according to the present embodiment will now be described in more detail with reference to FIG. 15. FIG. 15 is a flowchart for describing the method for forming the light-emitting layer 14 according to the present embodiment.

In the process of forming the blue light-emitting layer 14B according to the present embodiment, prior to step S10-2, the excess ligands 34 are removed from a blue quantum dot solution used for forming the blue quantum dot material layer 36B (step S10-18).

In step S10-18, for example, the blue quantum dot solution is centrifuged. Thus, the blue quantum dot solution is separated by centrifugation into a solution including the blue quantum dots 26B and the binding ligands 32 and a solution including the excess ligands 34. Here, with only the solution including the blue quantum dots 26B and the binding ligands 32 being extracted, a blue quantum dot solution in which the concentration of the excess ligands 34 is reduced is obtained.

Next, the blue quantum dot material layer 36B is formed by the same technique as that in step S10-2 according to the first embodiment. Here, the blue quantum dot material layer 36B is formed by using the solution of the blue quantum dots 26B in which the concentration of the excess ligands 34 was reduced by execution of step S10-18 described above.

Next, a cleaning liquid is dripped onto the blue quantum dot material layer 36B thus formed (step S10-20). The cleaning liquid may include, for example, alcohols or ethers, and may include a solvent in which the ligand 30 is highly soluble. Thus, at least a portion of the excess ligands 34 in the blue quantum dot material layer 36B is released into the cleaning liquid.

Next, the cleaning liquid is removed from the blue quantum dot material layer 36B into which the cleaning liquid was dripped (step S10-22). Step S10-22 may be implemented by, for example, inclining the blue quantum dot material layer 36B together for each substrate 4 and causing the cleaning liquid to flow from the blue quantum dot material layer 36B. In step S10-22, as the cleaning liquid is removed from the blue quantum dot material layer 36B, the excess ligands 34 released in the cleaning liquid are also removed by viscous resistance between the cleaning liquid and the excess ligands 34.

In the above-described process of cleaning the excess ligands 34 nanoscale in size with the cleaning liquid, a viscosity of the cleaning liquid significantly acts on an inertia of the excess ligands 34 due to the size effect. Therefore, the viscous resistance between the excess ligands 34 and the cleaning liquid efficiently acts, and the excess ligands 34 are effectively released into the cleaning liquid. Further, as the number of side chains of the excess ligands 34 increases, the viscous resistance between the excess ligands 34 and the cleaning liquid acts with greater strength, more efficiently discharging the excess ligands 34 with the cleaning liquid. Note that, in the case of removing the excess ligands 34 having a small number of side chains and a relatively low viscous resistance with the cleaning liquid, the cleaning process described above may be repeated a plurality of times.

The blue light-emitting layer 14B according to the present embodiment is obtained by sequentially executing step S10-4 to step S10-12 according to the first embodiment following step S10-22. The red light-emitting layer 14R and the green light-emitting layer 14G may be formed by partially changing the process of forming the blue light-emitting layer 14B described above in accordance with the method described in the first embodiment, and executing the changed process. With the above, the process of forming the light-emitting layer 14 according to the present embodiment can be executed.

The method for forming the blue light-emitting element 6B according to the present embodiment includes a process of reducing the excess ligands 34 from the blue quantum dot material layer 36B. By this formation method, the blue quantum dot layer 22B having a reduced concentration of the excess ligands 34 can be formed. In the method for forming the blue light-emitting element 6B according to the present embodiment, an example in which step S10-18, step S10-20, and step S10-22 are all executed has been described, but no such limitation is intended. For example, the concentration of the excess ligands 34 in the blue quantum dot layer 22B can be reduced by executing any one of step S10-18, step S10-20, and step S10-22.

Note that, in step S10-18 and step S10-22, a portion of the binding ligands 32 are considered detached from the blue quantum dots 26B and removed from the solution of the blue quantum dots 26B. In this case, the excess ligands 34 newly form coordination bonds with the blue quantum dots 26B from which a portion of the binding ligands 32 is detached, forming the binding ligands 32. With the binding ligands 32 and the excess ligands 34 in an equilibrium state with each other as described above, even when a portion of the binding ligands 32 is removed in the process described above, contribution to the reduction in the excess ligands 34 results.

Further, step S10-18, step S10-20, and step S10-22 according to the present embodiment may be applied to the blue quantum dot material layer 36B according to the previous embodiment, and may also be applied to the mixed layer 40B according to the previous embodiment. For example, in the previous embodiment, prior to step S10-14, the excess ligands 34 may be removed from the solution used for forming the mixed layer 40B. Furthermore, in the previous embodiment, after step S10-14, the dripping of the cleaning liquid into the mixed layer 40B and the removal of the cleaning liquid from the mixed layer 40B may be executed. Thus, the blue quantum dot layer 22B and the blue quantum dot layer 46B having a reduced concentration of the excess ligands 34 can be formed by the method for forming the blue light-emitting element 6B according to the previous embodiment.

### Fourth Embodiment

### Layered Structure of Quantum Dot Layer and Insulating Layer

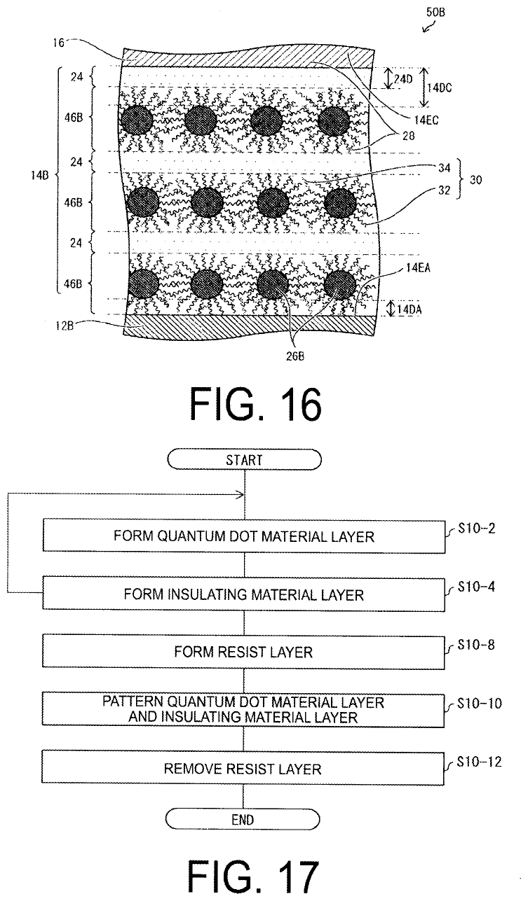

FIG. 16 is an enlarged schematic view illustrating a partial region of a schematic cross section of the display device 2 according to the present embodiment, and is an enlarged view of a position corresponding to the enlarged schematic view of the display device 2 illustrated in FIG. 1. As compared to the display device 2 according to the first embodiment, the display device 2 according to the present embodiment includes a red light-emitting element 50R, a green light-emitting element 50G, and a blue light-emitting element 50B instead of the red light-emitting element 6R, the green light-emitting element 6G, and the blue light-emitting element 6B, respectively. Otherwise, the display device 2 according to the present embodiment has the same configuration as that of the display device 2 according to the first embodiment.

The blue light-emitting element 50B according to the present embodiment, as compared with the blue light-emitting element 6B according to the first embodiment, differs in configuration in that the blue light-emitting layer 14B includes a plurality of the blue quantum dot layers 46B and a plurality of the insulating layers 24 alternately layered. The blue quantum dot layer 46B according to the present embodiment may have the same configuration as that of the blue quantum dot layer 46B according to the second embodiment. Further, the insulating layer 24 according to the present embodiment may have the same configuration as that of the insulating layer 24 according to each embodiment previously described.

Note that FIG. 16 illustrates the blue light-emitting layer 14B including the blue quantum dot layer 46B and the insulating layer 24 in quantities of three each, but no such limitation is intended. For example, the blue light-emitting layer 14B may include the blue quantum dot layer 46B and the insulating layer 24 in quantities of two each or in quantities of four or more each. Further, the thickness 24D of the insulating layer 24 may be the same in at least two layers, or may be different from each other.

In particular, the blue light-emitting layer 14B according to the present embodiment includes the blue quantum dot layer 46B with the end face 14EA on the anode 10 side formed by the end face, on the anode 10 side, of the blue quantum dot layer 46B positioned closest to the anode 10. Furthermore, the blue light-emitting layer 14B includes the insulating layer 24 with the end face 14EC on the cathode 18 side formed by the end face, on the cathode 18 side, of the insulating layer 24 positioned closest to the cathode 18. Therefore, in the present embodiment as well, the gap 14DA is smaller than the gap 14DC.

Otherwise, the blue light-emitting element 50B according to the present embodiment has the same configuration as that of the blue light-emitting element 6B according to the first embodiment.

The blue light-emitting element 50B reduces the occurrence of a reactive current and the occurrence of electron excess in the blue light-emitting layer 14B for the same reasons as those described in the first embodiment. Therefore, the blue light-emitting element 50B improves the luminous efficiency and extends the lifetime.

Furthermore, the blue light-emitting layer 14B according to the present embodiment includes the insulating layer 24 between the two blue quantum dot layers 46B as well. Therefore, the blue light-emitting layer 14B can reduce a reactive current propagating from a certain blue quantum dot layer 46B to another blue quantum dot layer 46B. Accordingly, the blue light-emitting element 50B according to the present embodiment can further reduce the generation of the reactive current in the blue light-emitting layer 14B.

Note that, in the present embodiment, an example is given in which the blue light-emitting layer 143 includes a plurality of the blue quantum dot layers 46B that do not include the insulating material 28, but no such limitation is intended. For example, the blue light-emitting layer 14B according to the present embodiment may include a plurality of the blue quantum dot layers 22B including the insulating material 28 described in each of the embodiments described above, instead of the blue quantum dot layer 46B. With this configuration, the blue light-emitting element 50B can more efficiently reduce the reactive current propagating between the blue quantum dots 26B.

Furthermore, as compared with the blue light-emitting element 50B, the red light-emitting element 50R and the green light-emitting element 50G according to the present embodiment have the same configuration except for the luminescent color of the quantum dots included in the light-emitting layer 14. Accordingly, each of the red light-emitting element 50R and the green light-emitting element 50G has the same effect as that of the blue light-emitting element 50B.

### Repetition of Film Formation Process

The display device 2 according to the present embodiment can be manufactured by a manufacturing method obtained by changing only the process of forming the light-emitting layer in the method for manufacturing the display device 2 according to the first embodiment. The method for forming the light-emitting layer 14 according to the present embodiment will now be described in more detail with reference to FIG. 17. FIG. 17 is a flowchart for describing the method for forming the light-emitting layer 14 according to the present embodiment.

In the process of forming the blue light-emitting layer 14B according to the present embodiment, first, step S10-2 and step S10-4 according to the first embodiment are alternately executed a plurality of times to obtain a layered structure of the blue quantum dot material layer 36B and the insulating material layer 38. Therefore, a process of curing the insulating material 28 included in the blue quantum dot material layer 36B and the insulating material layer 38 may be implemented every time the pair of steps S10-2 and S10-4 is executed.

In the present embodiment, the number of times step S10-2 and step S10-4 are executed is determined in accordance with the number of layers of the blue quantum dot layer 46B and the insulating layer 24 to be formed. After execution of step S10-2 and step S10-4 is completed the prescribed number of times, step S10-8 to step S10-12 according to the first embodiment are sequentially executed. In step S10-10 according to the present embodiment, the plurality of blue quantum dot material layers 36B and the insulating material layer 38 may be patterned at once.

With the above, the blue light-emitting layer 14B according to the present embodiment is obtained. The red light-emitting layer 14R and the green light-emitting layer 14G may be formed by partially changing the process of forming the blue light-emitting layer 14B described above in accordance with the method described in the first embodiment, and executing the changed process. With the above, the process of forming the light-emitting layer 14 according to the present embodiment can be executed.

The process of forming the blue light-emitting layer 14B according to the present embodiment does not include the process of forming the mixed layer 40B. For example, the formation process does not include a process of causing a portion of the insulating material 28 of the insulating material layer 38 to penetrate into the blue quantum dot material layer 36B, and does not include a process of forming the mixed layer 40B from a solution including the blue quantum dot material layer 26B and the insulating material 28. Therefore, by the process of forming the blue light-emitting layer 14B according to the present embodiment, the blue light-emitting layer 14B can be formed more simply.

However, the process of forming the blue light-emitting layer 14B according to the present embodiment is not limited to the processes described above. For example, in the process of forming the blue light-emitting layer 14B described above, the penetration process of causing a portion of the insulating material 28 in the insulating material layer 38 to penetrate into the blue quantum dot material layer 36B may be executed every time the pair of steps S10-2 and S10-4 is executed. The penetration process may be executed by the same technique as that in step S10-6 in the first embodiment. By this formation process, the blue light-emitting layer 14B including a plurality of the blue quantum dot layers 22B including the insulating material 28 can be formed.

### Fifth Embodiment

### Other Form of Light-Emitting Element

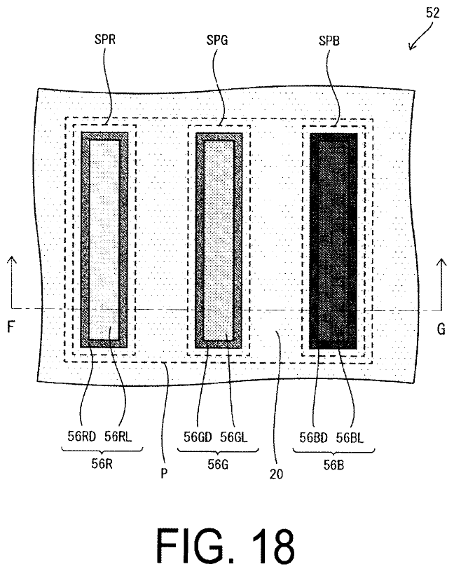

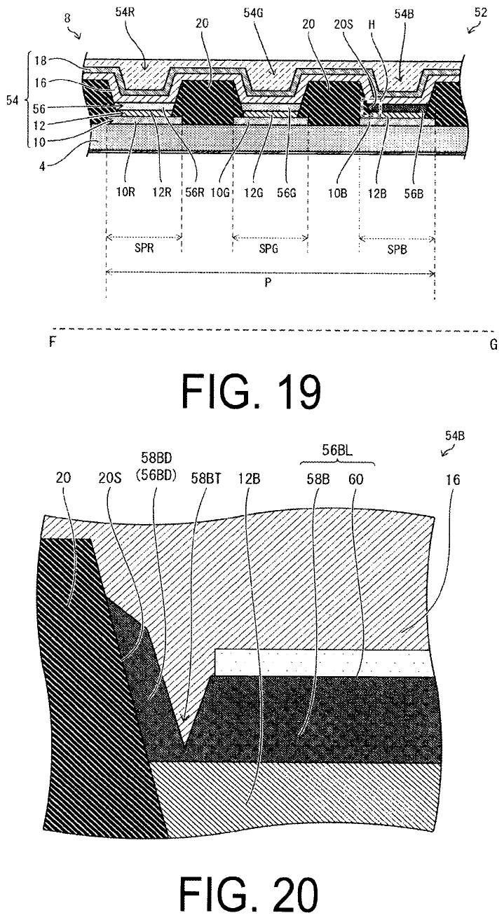

FIG. 18 is an enlarged schematic view of a partial region of the display region DA of a display device 52 according to the present embodiment, and is an enlarged view illustrating a position corresponding to the enlarged schematic view illustrated in FIG. 3. FIG. 19 is a schematic cross-sectional view of the display device 2 according to the present embodiment, and is a cross-sectional view taken along line F-G in FIG. 18. FIG. 20 is an enlarged schematic view of a cross section of the display device 2 according to the present embodiment, and is an enlarged view of a region H illustrated in FIG. 19. Note that, in FIG. 18, the sealing layer 8, the electron transport layer 16, and the cathode 18 are not illustrated as in FIG. 3.

The display device 52 according to the present embodiment, as compared with the display device 2 according to each embodiment described above, differs in configuration only in including a light-emitting element layer 54 instead of the light-emitting element layer 6. The light-emitting element layer 54, as compared with the light-emitting element layer 6 according to each embodiment described above, differs in configuration only in including a light-emitting layer 56 instead of the light-emitting layer 14.

In the present embodiment, the light-emitting element layer 54 includes, as light-emitting elements, a red light-emitting element 54R in the red subpixel SPR, a green light-emitting element 54G in the green subpixel SPG, and a blue light-emitting element 54B in the blue subpixel SPB.

In the present embodiment as well, the light-emitting layer 56 is separately formed on a subpixel-by-subpixel basis. In particular, in the present embodiment, the light-emitting layer 56 includes a red light-emitting layer 56R that emits red light, a green light-emitting layer 56G that emits green light, and a blue light-emitting layer 56B that emits blue light.

Accordingly, in the present embodiment, the red light-emitting element 54R is composed of the anode 10R, the hole transport layer 12R, the red light-emitting layer 56R, the electron transport layer 16, and the cathode 18. Further, the green light-emitting element 54G is composed of the anode 10G, the hole transport layer 12G, the green light-emitting layer 56G, the electron transport layer 16, and the cathode 18. Furthermore, the blue light-emitting element 54B is composed of the anode 10B, the hole transport layer 12G, the blue light-emitting layer 563, the electron transport layer 16, and the cathode 18.

Like the light-emitting layer 14, the light-emitting layer 56 is a layer that emits light as a result of an occurrence of recombination between the holes transported, via the hole transport layer 12, from the anode 10 and the electrons transported, via the electron transport layer 16, from the cathode electrode 18. However, the light-emitting layer 56 may include, as a luminescent body, a fluorescent material, a phosphorescent material, or the like in addition to a quantum dot material, and may include an organic material in addition to an inorganic material. For example, each light-emitting element according to the present embodiment may be a QLED element, or may be an organic light-emitting diode (OLED) element.

The light-emitting element layer 54 is separated into the red light-emitting element 54R, the green light-emitting element 54G, and the blue light-emitting element 54B by the bank 20 formed on the substrate 4. Further, the red light-emitting layer 56R, the green light-emitting layer 56G, and the blue light-emitting layer 56B are in contact with the side surface 20S of the bank 20.

As illustrated in FIG. 18, the red light-emitting layer 56R according to the present embodiment includes a main light-emitting portion 56RL and an outer edge portion 56RD. Further, the green light-emitting layer 56G according to the present embodiment includes a main light-emitting portion 56B and an outer edge portion 56GD. Furthermore, the blue light-emitting layer 56B according to the present embodiment includes the main light-emitting portion 56BL and the outer edge portion 56BD. The outer edge portion 56RD, the outer edge portion 56GD, and the outer edge portion 56BD, in plan view of the substrate 4, are disposed at positions surrounding the main light-emitting portion 56RL, the main light-emitting portion 56GL, and the main light-emitting portion 56BL, respectively. Therefore, each of the outer edge portion 56RD, the outer edge portion 56GD, and the outer edge portion 56BD is in contact with the side surface 20S of the bank 20.

### Main Light-Emitting Layer and Protection Layer

The main light-emitting portion and the outer edge portion of the light-emitting layer 56 according to the present embodiment will now be described in more detail with reference to an enlarged schematic view of the vicinity of an interface between the bank 20 and the light-emitting layer 56 illustrated in FIG. 20. FIG. 20, in particular, is an enlarged schematic view illustrating the vicinity of the interface between the bank 20 and the blue light-emitting layer 56B of the blue light-emitting element 54B of the display device 2 according to the present embodiment, and is an enlarged view illustrating the region H illustrated in FIG. 19. Herein, unless otherwise specified, the main light-emitting portion 56RL and the main light-emitting portion 56GL have the same configuration as that of the main light-emitting portion 56BL, and the outer edge portion 56RD and the outer edge portion 56GD have the same configuration as that of the outer edge portion 56BD, except for materials.

The main light-emitting portion 56BL includes a main light-emitting layer 58B including a blue light-emitting material included in the blue light-emitting layer 56B, and a protection layer 60 covering an upper face of the main light-emitting layer 58B, in this order from the substrate 4 side. The protection layer 60 may include the insulating material 28 described above, and may have the same configuration as that of the insulating layer 24, for example. When the protection layer 60 includes the insulating material 28, the protection layer 60 is an insulating layer having insulating properties. For example, the protection layer 60 is a layer including at least a material that is chemically more stable than the light-emitting material included in the main light-emitting layer 58B, such as an inorganic material. Note that the main light-emitting portion 56RL and the main light-emitting portion 56GL according to the present embodiment have the same configuration as that of the main light-emitting portion 56BL except that these include a light-emitting material layer including a red light-emitting material and a light-emitting material layer including a green light-emitting material, respectively.

On the other hand, the outer edge portion 56BD includes a deactivation layer 58BD and does not include the protection layer 60. The deactivation layer 58BD is in contact with the side surface 20S of the bank 20 and is continuous with the main light-emitting layer 58B of the main light-emitting portion 56BL with a thin film portion 58BT, having a thickness thinner than the surrounding portion, interposed therebetween.

However, the deactivation layer 58BD need not be continuous with the main light-emitting portion 56BL, and may be formed as a separate body. In other words, the blue light-emitting layer 56B may not be formed between the main light-emitting portion 56B and the outer edge portion 56BD, and the main light-emitting portion 56BL and the outer edge portion 56BD may be separated by the electron transport layer 16.

The deactivation layer 58BD includes a material in which the light-emitting material included in the main light-emitting layer 58B is deactivated by oxidation, moisture permeation, physical damage, or the like. Therefore, the deactivation layer 58BD has a low luminous efficiency compared to the main light-emitting layer 58B. Otherwise, the deactivation layer 58BD may have the same configuration as that of the main light-emitting layer 58B. Note that the outer edge portion 56RD and the outer edge portion 56GD according to the present embodiment have the same configuration as that of the outer edge portion 56BD except for including a deactivation layer including a material in which the red light-emitting material is deactivated and a deactivation layer including a material in which the green light-emitting material is deactivated, respectively.

### Method for Forming Light-Emitting Material Layer and Protection Layer

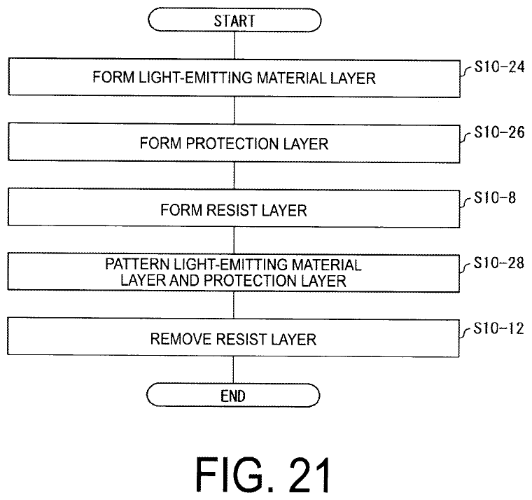

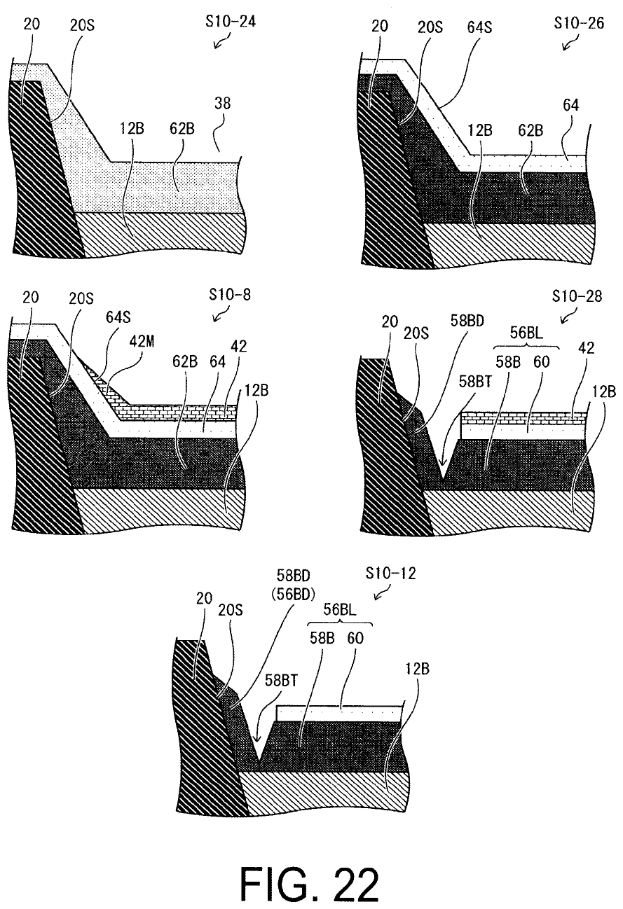

The display device 52 according to the present embodiment can be manufactured by the same method as the method for manufacturing the display device 2 according to each of the embodiments described above by changing only the formation process of the light-emitting layer. The method for forming the light-emitting layer 56 according to the present embodiment will now be described in more detail with reference to FIG. 21 and FIG. 22. Hereinafter, the method for forming the light-emitting layer 56 in the present embodiment will be described by using the method for forming the blue light-emitting layer 56B as a representative. FIG. 21 is a flowchart for describing the method for forming the light-emitting layer 56 according to the present embodiment. FIG. 22 illustrates process cross-sectional views of the vicinity of the side surface 20S of the bank 20 positioned in the blue subpixel SPB in the process of forming the light-emitting layer 56 according to the present embodiment. Note that each process cross-sectional view illustrated in FI. 22 illustrates a cross section at a position corresponding to the cross section illustrated in FIG. 20.

In the process of forming the blue light-emitting layer 56B according to the present embodiment, first, a light-emitting material layer 62B is formed by forming a thin film including a blue light-emitting material on the entire surface of an upper layer overlaying the hole transport layer 12B and the bank 20 (step S10-24). In other words, in step S10-24, the light-emitting material layer 62B is formed not only for the blue subpixel SPB but also for the red subpixel SPR and the green subpixel SPG. Therefore, the light-emitting material layer 62B is formed on the side surface 20S of the bank 20 as well.

Next, a material including the protection layer 60 is formed on the light-emitting material layer 62B, thereby forming the protection layer 64 (step S10-26). The protection layer 64 is also formed on the entire upper face of the light-emitting material layer 62B. Therefore, on an upper face of the protection layer 64, an inclined face 64S reflecting the inclination of the side surface 20S of the bank 20 is formed around the blue subpixel SPB.

Note that the light-emitting material layer 62B and the protection layer 64 may be formed by applying a solution including the insulating material 28 by an application method using a coater, for example. Alternatively, the light-emitting material layer 62B and the protection layer 64 may be formed by, for example, vapor deposition or an electrodeposition method.

Next, the resist layer 42 is formed in an upper layer overlying the protection layer 64 for each blue subpixel SPB by the same technique as that in step S10-8 according to the embodiments described above. In the present embodiment as well, a portion of the resist layer 42 formed at a position adjacent to the inclined face 64S creeps up the inclined face 64S due to the meniscus effect. Accordingly, after execution of step S10-8, the light-emitting material layer 62B and the protection layer 64 are covered with the outer edge portion 42M of the resist layer 42 at a position overlapping the side surface 20S of the bank 20 in plan view of the substrate 4, the outer edge portion 42M being relatively thin.

Next, the light-emitting material layer 62B and the protection layer 64 are etched by an appropriate etching method to pattern the light-emitting material layer 62B and the protection layer 64 (step S10-28). The light-emitting material layer 62B and the protection layer 64 may be etched by using, for example, the etching material used in step S10-10 according to the embodiments described above. As a result, the light-emitting material layer 62B having an island shape and the protection layer 64 are formed for each blue subpixel SPB, and become the main light-emitting layer 58B and the protection layer 60, respectively.

In the present embodiment as well, when step S10-8 is completed, the resist layer 42 is also thinly formed as the outer edge portion 42M on the inclined face 64S of the protection layer 64 positioned around the blue subpixel SPB. Therefore, by execution of step S10-28, a portion of the light-emitting material layer 62B remains on the side surface 20S of the bank 20 without being etched. However, the light-emitting material layer 62B at this position is exposed to the etching material under the same circumstances as those described in the first embodiment.

In particular, the etching in the step S10-28 is executed by dry etching or wet etching. In this case, the blue light-emitting material remaining on the side surface 20S of the bank 20 and included in the light-emitting material layer 62B exposed to the etching material is deteriorated and deactivated by oxidation or the like. Therefore, when step S10-28 is completed, the deactivation layer 58BD is formed on the side surface 20S of the bank 20.

Next, the resist layer 42 is removed from the protection layer 64 by the same technique as that in step S10-12 according to the previous embodiment. Thus, the main light-emitting portion 563L, including the main light-emitting layer 58B and the protection layer 60, and the outer edge portion 563D, including the deactivation layer 58BD, are obtained, thereby completing the process of forming the blue light-emitting layer 56B.

The red light-emitting layer 56R and the green light-emitting layer 56G may be formed by partially changing the process of forming the blue light-emitting layer 56B described above, and executing the changed process. For example, in the process of forming the red light-emitting layer 56R and the green light-emitting layer 56G, the blue light-emitting material included in the light-emitting material layer 62B in the process of forming the blue light-emitting layer 56B is changed to a red light-emitting material and a green light-emitting material, respectively. Further, in the process of forming the red light-emitting layer 56R and the green light-emitting layer 56G, the position where the resist layer 42 is formed in step S10-8 described above is changed to positions overlapping the red subpixel SPR and the green subpixel SPG, respectively, in plan view of the substrate 4. With the above, the process of forming the light-emitting layer 56 according to the present embodiment can be executed.

In step S10-8 according to the present embodiment, the protection layer 64 is formed in an upper layer overlying the light-emitting material layer 62B. Therefore, even when the material included in the protection layer 64 is deteriorated by contact with the developing solution described above, the protection layer 64 can reduce contact between the light-emitting material layer 62B and the developing solution described above. Further, the protection layer 64 may include a chemically stable material as compared with the light-emitting material included in the light-emitting material layer 62B. In this case, even in a case in which the developing solution used for patterning the resist layer 42 comes into contact with the protection layer 64, the deterioration of the protection layer 64 is reduced as compared with the deterioration of the light-emitting material of the light-emitting material layer 62B when the developing solution comes into contact with the light-emitting material layer 62B. Accordingly, the protection layer 64 can protect the light-emitting material layer 62B from the developing solution used for patterning the resist layer 42, and reduces deterioration of the blue light-emitting material included in the light-emitting material layer 62B.

Further, in step S10-28 according to the present embodiment, the patterning of the light-emitting material layer 62B and the protection layer 64 is executed by dry etching or wet etching. Therefore, by step S10-28, at the position covered with the outer edge portion 42M of the resist layer 42, the deactivation layer 58BD, including the deactivated blue light-emitting material, and the outer edge portion 56BD, including the deactivation layer 58BD, are formed.

Thus, the outer edge portion 56BD of the blue light-emitting element 54B formed by the formation method described above, with the included blue light-emitting material being deactivated, has a luminous efficiency that is significantly reduced. Accordingly, by forming the blue light-emitting element 54B by the formation method described above, abnormal light emission of the outer edge portion 56BD can be reduced.

Therefore, the blue light-emitting element 54B can make the carriers injected into the blue light-emitting layer 56B efficiently contribute to the light emission of the main light-emitting portion 56BL, thereby improving the luminous efficiency of the main light-emitting portion 56BL. Further, the blue light-emitting element 54B includes the outer edge portion 56BD having a low luminous efficiency at an outer edge of the main light-emitting portion 56BL. Therefore, the blue light-emitting element 54B can reduce the light emission intensity at or near the boundary with the other light-emitting elements. As a result, the display device 2 including the blue light-emitting element 54B can reduce color mixing between subpixels, improving the display quality.

Furthermore, in step S10-12 according to the present embodiment, the protection layer 60 is formed in an upper layer overlying the main light-emitting layer 58B. For this reason, the protection layer 60 can protect the main light-emitting layer 58B from the remover used for removing the resist layer 42, thereby reducing deterioration of the blue light-emitting material.

Note that the protection layer 60 according to the present embodiment is an insulating layer including the insulating material 28. Therefore, in the main light-emitting portion 56BL in which the protection layer 60 is provided at a position in contact with the end face of the main light-emitting layer 58B on the cathode 18 side, the electron excess in the main light-emitting layer 58B is reduced due to the circumstances described in the embodiments described above. Accordingly, the blue light-emitting element 54B according to the present embodiment improves the luminous efficiency of the blue light-emitting layer 56B.

The methods for forming the red light-emitting element 54R and the green light-emitting element 54G according to the present embodiment can be executed by only changing each light-emitting material and the formation position of each light-emitting layer 56 in the method for forming the blue light-emitting element 54B. Accordingly, the methods for forming the red light-emitting element 54R and the green light-emitting element 54G according to the present embodiment also achieve the same effects as those of the method for forming the blue light-emitting element 54B.

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

### REFERENCE SIGNS LIST

2, 52 Display device
4 Substrate
6, 54 Light-emitting element layer
6B, 54B Blue light-emitting element (light-emitting element)
10 Anode
14, 56 Light-emitting layer
18 Cathode
20 Bank
22B, 46B Blue quantum dot layer (quantum dot layer)
24 Insulating layer
261B Blue quantum dot (quantum dot)
28 Insulating material
30 Ligand (first compound)
36B Blue quantum dot material layer (quantum dot material layer)
38 Insulating material layer
40B Mixed layer
42 Resist layer
58B Main light-emitting layer
60, 64 Protection layer
62B Light-emitting material layer

1. A light-emitting element comprising:
an anode;
a light-emitting layer; and
a cathode,
wherein the anode, the light-emitting layer, and the cathode are disposed in this order,
the light-emitting layer includes a plurality of quantum dots and an insulating material, and
an average value of a gap between a quantum dot of the plurality of quantum dots in an end face portion of the light-emitting layer on a side of the anode and an end face of the light-emitting layer on the side of the anode is less than an average value of a gap between a quantum dot of the plurality of quantum dots in an end face portion of the light-emitting layer on a side of the cathode and an end face of the light-emitting layer on the side of the cathode.

2. The light-emitting element according to claim 1,
wherein, when the light-emitting layer is equally divided, in a layering direction of the light-emitting element, into three portions, a first portion including the end face on the side of the anode, a second portion positioned further on the side of the cathode than the first portion, and a third portion positioned even further on the side of the cathode than the second portion and including the end face on the side of the cathode, an average density of the insulating material increases in the order of the first portion, the second portion, and the third portion.

3. The light-emitting element according to claim 1,
wherein the light-emitting layer further includes a plurality of first compounds that can coordinate to at least one of the plurality of quantum dots,
at least one of the plurality of quantum dots or the plurality of first compounds is in contact with the end face on the side of the anode, and
at least one of the plurality of quantum dots or the plurality of first compounds is adjacent to the end face on the side of the cathode with the insulating material interposed between the at least one of the plurality of quantum dots or the plurality of first compounds and the end face on the side of the cathode.

4. The light-emitting element according to claim 1,
wherein the insulating material has a carrier mobility of less than 10⁻⁶ cm²/V·sec.

5. The light-emitting element according to claim 1,
wherein the insulating material includes an amorphous material.

6. The light-emitting element according to claim 5,
wherein the insulating material includes at least one of a glass-based material, a tetrafluoroethylene-based material, or a silicone-based material.

7. The light-emitting element according to claim 6,
wherein the light-emitting layer includes a compound derived from at least one solvent of an ether-based solvent, a perfluoro-based solvent, or a hydrocarbon-based solvent.

8. The light-emitting element according to claim 1,
wherein the insulating material includes a tetrafluoroethylene-based material,
the light-emitting layer includes
at least one first compound that can coordinate to at least one of the plurality of quantum dots, and
a second compound derived from a solvent including a perfluoro-based solvent, and
the at least one first compound is soluble in the perfluoro-based solvent.

9. The light-emitting element according to claim 3,
wherein the at least one first compound includes a binding compound and an excess compound having a higher free energy with respect to molecular weight than the binding compound, and
a ratio of a quantity of the excess compound to a total quantity of the at least one first compound is 1/(2n) or less, where n is a total quantity of carbon atoms, halogen atoms, group III atoms, group IV atoms, group V atoms, group VI atoms, and hydrogen chains of the excess compound.

10. (canceled)

11. The light-emitting element according to claim 1,
wherein the light-emitting layer includes an insulating layer,
the insulating layer forms the end face of the light-emitting layer on the side of the cathode and includes the insulating material,
the light-emitting layer includes a quantum dot layer including at least the plurality of quantum dots and forming the end face of the light-emitting layer on the side of the anode, and
the light-emitting layer includes a plurality of the quantum dot layers and a plurality of the insulating layers alternately layered.

12-15. (canceled)

16. A method for manufacturing a light-emitting element including an anode, a light-emitting layer, and a cathode disposed in this order, the method comprising:
forming the anode;
forming the light-emitting layer including a plurality of quantum dots and an insulating material; and
forming the cathode,
wherein the forming the light-emitting layer includes
forming a quantum dot material layer including the plurality of quantum dots, and
forming an insulating material layer including the insulating material,
in the forming the light-emitting layer, the forming the insulating material layer is performed after the forming the quantum dot material layer,
in the forming the insulating material layer, the insulating material layer is formed in an upper layer overlying the quantum dot material layer, and
the forming the light-emitting layer further includes causing a portion of the insulating material in the insulating material layer to penetrate into the quantum dot material layer after the forming the insulating material layer.

17. The method for manufacturing a light-emitting element, according to claim 16,
wherein the forming the light-emitting layer further includes forming a mixed layer including the plurality of quantum dots and the insulating material.

18. The method for manufacturing a light-emitting element, according to claim 16,
wherein the forming the quantum dot material layer includes applying a quantum dot solution including the plurality of quantum dots and at least one first compound that can coordinate to at least one of the plurality of quantum dots, to form the quantum dot material layer.

19. The method for manufacturing a light-emitting element, according to claim 18,
wherein the forming the quantum dot material layer further includes centrifuging the quantum dot solution to reduce a concentration of the at least one first compound included in the quantum dot solution prior to the applying the quantum dot solution.

20. The method for manufacturing a light-emitting element, according to claim 18,
wherein the forming the quantum dot material layer further includes dripping a cleaning liquid including at least one of an alcohol or an ether onto the quantum dot material layer after the applying the quantum dot solution, and
removing the cleaning liquid from the quantum dot material layer after the dripping the cleaning liquid, thereby removing at least one of the at least one first compound included in the quantum dot material layer at the same time.

21. A method for manufacturing a display device including a plurality of light-emitting elements formed on a substrate on a subpixel-by-subpixel basis by the method for manufacturing a light-emitting element according to claim 16,
wherein the forming the light-emitting layer further includes patterning the quantum dot material layer and the insulating material layer on a subpixel-by-subpixel basis after the forming the insulating material layer.

22. The method for manufacturing a display device, according to claim 21, further comprising:
forming, on the substrate, a bank separating the light-emitting layer on a subpixel-by-subpixel basis prior to the forming the light-emitting layer,
wherein a face of the bank in contact with the light-emitting layer is a forwardly tapered face, and
in the patterning the quantum dot material layer and the insulating material layer, the quantum dot material layer and the insulating material layer are patterned on a subpixel-by-subpixel basis by dry etching or wet etching the quantum dot material layer and the insulating material layer.

23. The method for manufacturing a display device, according to claim 21,
wherein, in the patterning the quantum dot material layer and the insulating material layer, the quantum dot material layer and the insulating material layer are patterned on a subpixel-by-subpixel basis by dry etching, using O₂ or O₂ plasma, the quantum dot material layer and the insulating material layer.

24. A display device comprising:
a substrate;
a plurality of light-emitting elements disposed on a subpixel-by-subpixel basis on the substrate; and
a bank separating the plurality of light-emitting elements on a subpixel-by-subpixel basis,
wherein each of the plurality of light-emitting elements includes an anode, a light-emitting layer, and a cathode disposed in this order,
the light-emitting layer includes a main light-emitting portion including a light-emitting material, and
an outer edge portion disposed at a position surrounding the main light-emitting portion in plan view of the substrate, and including a deactivation material in which the light-emitting material is deactivated, and
the bank includes a forwardly tapered face on a side surface, and is in contact with the outer edge portion at the forwardly tapered face.

25. The display device according to claim 24,
wherein the main light-emitting portion includes a main light-emitting layer including the light-emitting material, and
an insulating layer in contact with the main light-emitting layer on a side of the cathode.

26. (canceled)
